(19) United States
(12) Patent Application Publication
(10) Pub. No.: US 2017/0216814 A1
(43) Pub. Date: Aug. 3, 2017

(54) FILTRATION MATERIAL, FILTRATION FILTER, METHOD FOR MANUFACTURING FILTRATION MATERIAL, FILTRATION METHOD, COPOLYMER, AND METHOD FOR MANUFACTURING COPOLYMER

(71) Applicant: TOKYO OHKA KOGYO CO., LTD., Kawasaki-shi (JP)

(72) Inventor: Isao HIRANO, Kawasaki-shi (JP)

(73) Assignee: TOKYO OHKA KOGYO., LTD., Kawasaki-shi (JP)

(21) Appl. No.: 15/501,137

(22) PCT Filed: Aug. 7, 2015
(86) PCT No.: PCT/JP2015/072510

§ 371 Date: Feb. 1, 2017

(30) Foreign Application Priority Data
Aug. 11, 2014 (JP) 2014-163873
Aug. 11, 2014 (JP) 2014-163943
Mar. 25, 2015 (JP) 2015-063037

(51) Int. Cl. B01J 20/22; B01J 20/28; B01J 20/26; B01J 20/283; B01J 20/291; B01D 15/08; B01J 20/32; G03F 7/26; C08G 77/392; C08J 3/075; C08J 9/28; B01J 20/10; B01J 20/289

(52) U.S. Cl. CPC B01J 20/22; B01J 20/103; B01J 20/28023; B01J 20/28047; B01J 20/28004; B01J 20/28016; B01J 20/264; B01J 20/283; B01J 20/291; B01J 20/289; B01J 20/3293; B01J 20/3257; B01J 20/3219; B01J 20/3204; B01J 20/3212; G03F 7/26; C08G 77/392; C08J 3/075; C08J 9/28; B01D 15/08; B01J 2220/54; C08J 2205/028; C08G 2101/0091

(57) ABSTRACT

A filtration material including a silica base material having a group represented by the following general formula (a0-1) [in formula (a0-1), Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the silica base material].

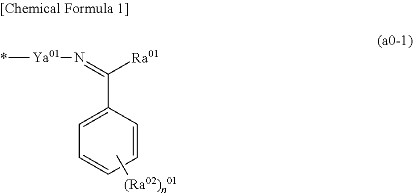

### TECHNICAL FIELD

The present invention relates to a filtration material, a filtration filter, a method for producing a filtration material, a filtration method, a copolymer and a method for producing a copolymer.

Priority is claimed on Japanese Patent Application No. 2014-163873 and Japanese Patent Application No. 2014-163943, filed Aug. 11, 2014, and Japanese Patent Application No. 2015-063037 filed Mar. 25, 2015, the contents of which are incorporated herein by reference.

### BACKGROUND ART

Resist compositions are used in lithography processes for manufacturing miniaturized electronic components.

Generally, in these processes, first, a resist composition is applied to a base material such as a silicon wafer to form a resist film, and the resist film is subjected to selective exposure of radial rays such as light or electron beam through a mask having a predetermined pattern, followed by development, thereby forming a resist pattern having a predetermined shape on the resist film.

In recent years, processing of a further ultra-fine pattern has been required for manufacturing semiconductor substrates.

In such applications, particularly excellent lithography properties are required for the resist composition.

In addition, materials such as activated carbon, zeolite and silica gel have been widely used conventionally as the fillers and scavengers used for filtration and purification.

In recent years, in the production of ultrafine patterns, it is desired to also remove extremely small impurities of very low concentrations.

In the manufacture of an ultra-fine pattern, it is often observed that lithography characteristics are adversely affected by the presence of impurities that are considered to be metal ions with an extremely low concentration.

It is found that metal ion contamination of a resist composition is a cause of this problem. Further, it has been confirmed that the lithography characteristics are adversely affected just by the presence of less than 100 ppb (parts per billion) of metal ions in a resist composition.

In order to solve the above-described problems, attempts have been made to remove impurities such as metal ions by filtering and purifying materials such as resist compositions.

For example, Patent Literatures 1 and 2 describe a method of filtering a resist composition using a filter sheet or the like that uses a functionalized silica gel.

Patent Literature 3 describes a method of removing impurities using an impurity filtration device that has polyolefin non-woven fabric with a specific fiber diameter and a specific density as a filtration member. Patent Literatures 4 to 6 describe a method of removing metals using a predetermined filtering medium. Patent Literature 7 describes a method of removing impurity metal components using an adsorbent.

### CITATION LIST

### Patent Literature

[Patent Literature 1] Japanese Unexamined Patent Application, First Publication No. 2006-136883

[Patent Literature 2] Japanese Unexamined Patent Application, First Publication No. 2003-238958

[Patent Literature 3] Japanese Unexamined Patent Application, First Publication No. 2013-61426

[Patent Literature 4] Japanese Unexamined Patent Application, First Publication No. 2000-281739

[Patent Literature 5] Japanese Unexamined Patent Application, First Publication No. 2004-330056

[Patent Literature 6] Japanese Unexamined Patent Application, First Publication No. 2005-243728

[Patent Literature 7] Japanese Unexamined Patent Application, First Publication No. Hei 7-74073

### SUMMARY OF INVENTION

### Technical Problem

However, as the line width required for the manufacture of a semiconductor substrate has been further miniaturized and even the removal of extremely small impurities of low concentrations has been desired, the presence of metal impurities at parts per trillion (ppt) level cannot be neglected, and there is a demand for a filtration material with high removal efficiency for impurities including the metal components.

The present invention takes the above circumstances into consideration, with an object of providing a filtration material that exhibits high removal efficiency for metal components, a copolymer, and a method for producing the copolymer.

### Solution to Problem

A first aspect of the present invention is a filtration material including a silica base material having a group represented by the following general formula (a0-1).

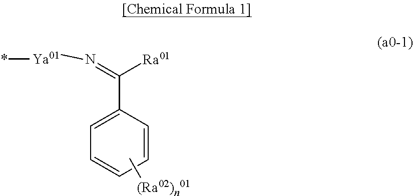

[In formula (a0-1), Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the silica base material.]

A second aspect of the present invention is a filtration material including a porous base material having a group represented by the following general formula (a0-1).

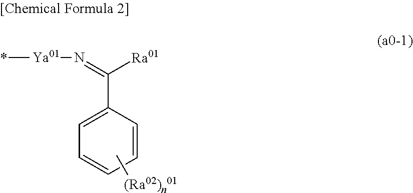

[In formula (a0-1), Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the porous base material.]

A third aspect of the present invention is a filtration filter including the filtration material according to the first or second aspect.

A fourth aspect of the present invention is a filtration method including a step of passing a resist composition or an organic solvent through the filtration filter according to the third aspect to remove impurities in the resist composition or the organic solvent.

A fifth aspect of the present invention is a method for producing a filtration material, the method including a step of introducing a group represented by the following general formula (a0-1) to a porous base material having a terminal amino group.

A sixth aspect of the present invention is a filtration method including a step of passing a resist composition or an organic solvent through the filtration material obtained according to the fifth aspect of the present invention to remove impurities in the resist composition or the organic solvent.

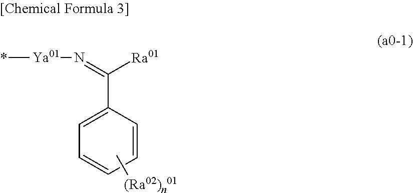

[In formula (a0-1), Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the porous base material having a terminal amino group.]

A sixth aspect of the present invention is a copolymer of an alkoxysilane having two or more functional groups, the copolymer having a partial structure represented by the following general formulas (p-1) and (p-3).

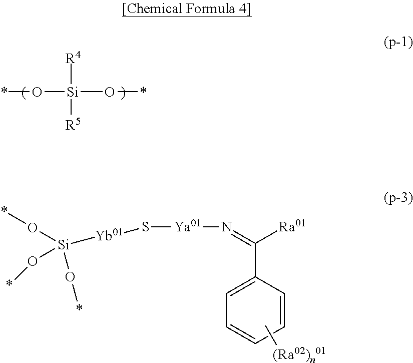

[In the formulas, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

A seventh aspect of the present invention is a copolymer of an alkoxysilane having two or more functional groups, the copolymer having a partial structure represented by the following general formulas (p-1) and (p-5).

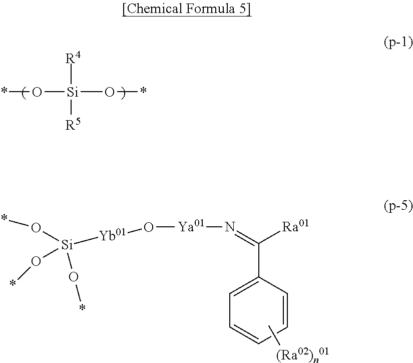

[In the formulas, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

An eighth aspect of the present invention is a method for producing the copolymer, the method including: a step A of reacting a compound represented by the following general formula (1) with a compound represented by the following general formula (2) to obtain a copolymer (A) having a partial structure represented by the following general formulas (p-1) and (p-2); a step B of modifying the copolymer (A) obtained in the step A to obtain a copolymer (B) having a partial structure represented by the following general formula (p-B-1); and a step C of modifying the copolymer (B) obtained in the step B to obtain a copolymer (C) having a partial structure represented by the following general formulas (p-3) and (p-1).

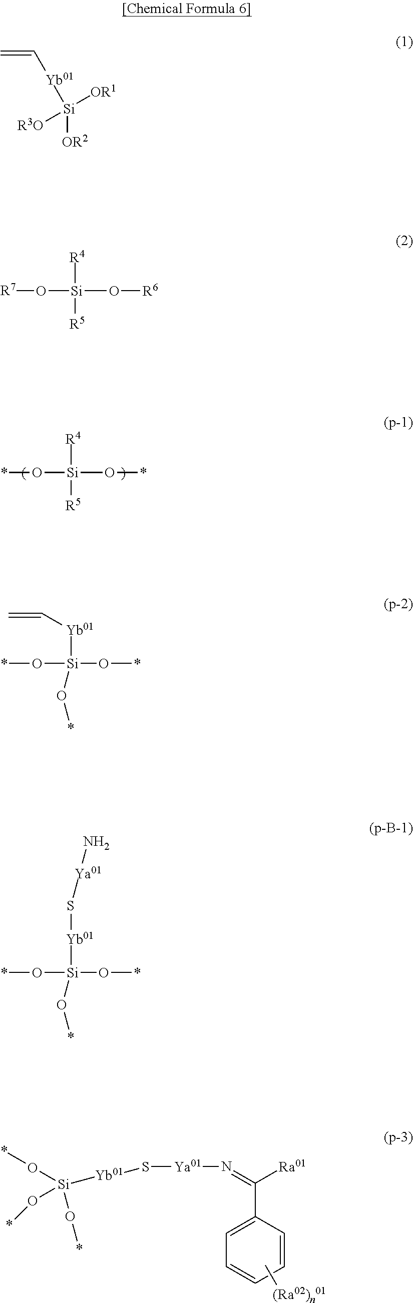

[In the formulas, R¹ to R³ and R⁶ to R⁷ each independently represent an alkyl group having 1 to 5 carbon atoms; R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

A ninth aspect of the present invention is a method for producing the copolymer, the method including: a step X of reacting a compound represented by the following general formula (3) with a compound represented by the following general formula (2) to obtain a copolymer (X) having a partial structure represented by the following general formulas (p-1) and (p-4); a step Y of modifying the copolymer (X) obtained in the step X to obtain a copolymer (Y) having a partial structure represented by the following general formula (p-Y-1); and a step Z of modifying the copolymer (Y) obtained in the step Y to obtain a copolymer (Z) having a partial structure represented by the following general formulas (p-5) and (p-1).

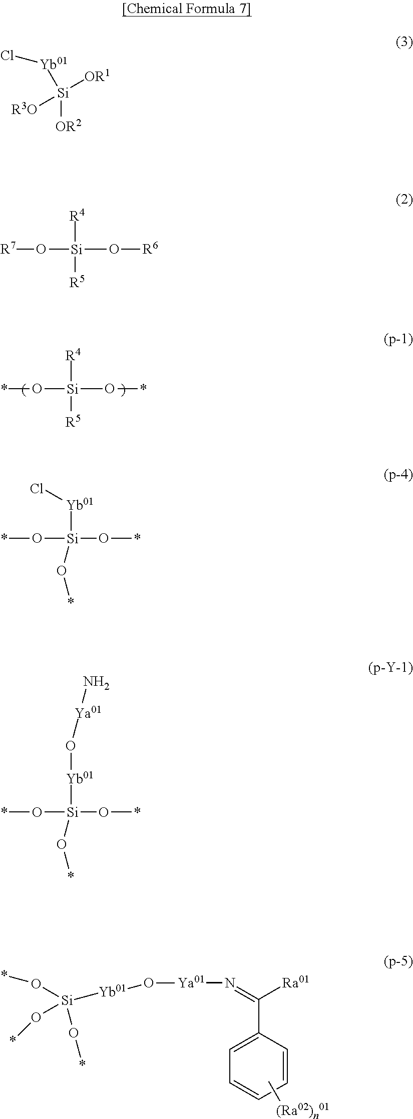

[In the formulas, R¹ to R³ and R⁶ to R⁷ each independently represent an alkyl group having 1 to 5 carbon atoms; R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

A tenth aspect of the present invention is a copolymer of an alkoxysilane having two or more functional groups, the copolymer having a partial structure represented by the following general formulas (p-1) and (p-4).

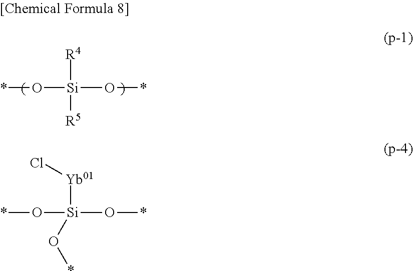

[In the formulas, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Yb⁰¹ represents a divalent linking group; and the symbol “*” represents a valence bond.]

### Advantageous Effects of Invention

According to the present invention, it is possible to provide a filtration material that exhibits high removal efficiency for metal components, a copolymer, and a method for producing the copolymer.

### DESCRIPTION OF EMBODIMENTS

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies for the alkyl group within an alkoxy group.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (resin, polymer, copolymer).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (Rα) with which the hydrogen atom bonded to the carbon atom at the α-position is substituted is an atom other than the hydrogen atom or a group, and examples thereof include an alkyl group having from 1 to 5 carbon atoms, a halogenated alkyl group having from 1 to 5 carbon atoms, and a hydroxyalkyl group. A carbon atom on the α-position of an acrylate ester refers to the carbon atom bonded to the carbonyl group, unless specified otherwise.

Hereafter, an acrylate ester in which a hydrogen atom bonded to the carbon atom on the α-position has been substituted with a substituent is sometimes referred to as an α-substituted acrylate ester. Further, acrylate esters and α-substituted acrylate esters are collectively referred to as “(α-substituted) acrylate ester”.

A “structural unit derived from hydroxystyrene or hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxyl group has been substituted with an organic group and may have the hydrogen atom on the α-position substituted with a substituent; and hydroxystyrene which has a substituent other than a hydroxyl group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include vinylbenzoic acid in which the hydrogen atom of the carboxy group has been substituted with an organic group and may have the hydrogen atom on the α-position substituted with a substituent; and vinylbenzoic acid which has a substituent other than a hydroxyl group and a carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The concept of a “styrene derivative” includes derivatives obtained by a hydrogen atom at the α-position of styrene being substituted with other substituents such as an alkyl group or a halogenated alkyl group.

A “structural unit derived from styrene” or a “structural unit derived from a styrene derivative” indicates a structural unit formed by cleavage of an ethylenic double bond of styrene or a styrene derivative.

As the alkyl group as a substituent on the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxyl groups within the hydroxyalkyl group is preferably 1 to 5, and most preferably 1.

The case of describing “may have a substituent” includes both of the case where the hydrogen atom (—H) is substituted with a monovalent group and the case where the methylene group (—CH₂—) is substituted with a divalent group.

The term “exposure” is used as a general concept that includes irradiation with any form of radiation.

An “organic group” indicates a group including carbon atoms, and the group may include atoms other than carbon atoms (such as hydrogen atoms, oxygen atoms, nitrogen atoms, sulfur atoms, and halogen atoms (fluorine atoms, chlorine atoms, and the like)).

### <<Filtration Material 1>>

The filtration material according to the first aspect of the present invention includes a silica base material having a group represented by general formula (a0-1).

The filtration material of the present embodiment is used for applications of filling a filter cartridge or a column and being disposed in the inside of a filtration device.

In particular, the filtration material of the present embodiment is preferably used for filtering a resist composition or an organic solvent.

For example, there is an application in which a resist composition or an organic solvent is passed through a filter cartridge or a column packed with the filtration material of the present embodiment and filtered.

Further, the filtration material of the present embodiment may be added to a resist composition or an organic solvent, stirred, and then mixed (for example, mixed by shaking the solution or causing rotational motion in a bottle). In this case, after the solution is stirred and mixed, the mixed solution of the filtration material and the resist composition or organic solvent may be filtered through a suitable filter.

The filtration material of the present embodiment includes a silica base material having a group represented by general formula (a0-1).

### (Silica)

In the present embodiment, silica (hereinafter, sometimes referred to as “silica base material”) is silicon dioxide (SiO₂) or a substance composed of silicon dioxide, but it is at least a silicon compound having a siloxane binding portion or a silanol group on the surface.

The main component of silica is silicon dioxide, but it may contain alumina, sodium aluminate, or the like as a minor component, and may further contain an inorganic base such as sodium hydroxide, potassium hydroxide, lithium hydroxide and ammonia, an organic base such as tetramethylammonium, or the like as a stabilizer.

In the present embodiment, the silica may be a silica fiber or silica particle formed from a glass product such as quartz glass, borosilicate glass or the like, but it is preferable to use a porous silica base material or silica gel.

Representative examples of the porous silica base material include a silica xerogel and a silica aerogel. These materials are produced by a sol-gel reaction. Here, the sol-gel reaction is a reaction in which colloidal matter called sol obtained by dispersing particles in a liquid is converted into a solid gel as an intermediate. In the case of silica, for example, when an alkoxysilane compound is used as a raw material, a gel precursor obtained by the hydrolysis and condensation reaction of the compound is dispersed in a solvent to form a sol. Furthermore, a crosslinked body in which the gel precursor contains a solvent by a condensation reaction is a gel. When the solvent is removed from the gel, it is possible to produce a silica xerogel exhibiting a xerogel structure in which only a solid network remains.

In the present embodiment, the porous silica base material is preferably synthesizable under metal-free conditions and has a high specific surface area. Porous silica fibers can also be suitably adopted as having a high specific surface area. Further, the porous silica base material preferably has high solvent absorbency and also has flexibility. In the present embodiment, a porous and flexible silica fiber is more preferable as the porous silica having the above requirements. Furthermore, there are many possibilities for selecting functional groups, and, for example, from the viewpoint of facilitating powder processing, it is preferable that the tensile strength of the porous silica be small when being processed into a powder.

In the present embodiment, examples of the porous silica include those having a porosity of 30 to 95% and a maximum pore size of 200 nm or less.

Silica gel is a common name for three-dimensional aggregates having a high density of colloidal silica fine particles, and is an amorphous porous body of silicon dioxide. Commercially available products include crushed or spherical particles having a particle diameter of several μm to several mm and a pore diameter of approximately 2 to 50 nm.

The surface of the silica gel is covered with a siloxane structure portion or silanol group and can adsorb polar molecules due to hydrogen bonding or polarity.

The silica gel has weakly acidic OH groups on the surface and these can be modified with amino groups.

In the present embodiment, the particle diameter of the silica gel is not particularly limited, and those having a particle diameter ranging from 0.1 μm up to 10 mm can be widely used.

Silica gel having a particle diameter of several μm has a large surface area, and is therefore suitably used from the viewpoint of adsorption and removal of impurities. In this case, the particle diameter is preferably from 1 to 100 μm, more preferably from 1.5 to 70 μm, and particularly preferably from 2 to 50 μm.

Further, silica gel having a particle diameter of several mm can be suitably used since filtering is easily carried out after adsorption and removal of impurities. In this case, the particle diameter is preferably from 1 to 10 mm, and more preferably from 2 to 7 mm.

The filtration material of the present embodiment is characterized in that a silica base material into which a group represented by the following general formula (a0-1) is introduced is used for silica. The group represented by general formula (a0-1) has a chelating ability, and the silica into which the group represented by the general formula (a0-1) has been introduced may be referred to as “chelating silica” in the present specification.

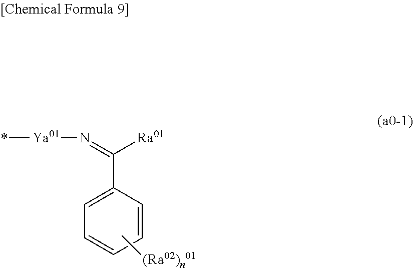

[In formula (a0-1), Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the silica base material.]

In formula (a0-1), Ya⁰¹ represents a divalent linking group.

The divalent linking group for Ya⁰¹ is not particularly limited, and preferred examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

### [Aliphatic Hydrocarbon Group]

An “aliphatic hydrocarbon group” refers to a hydrocarbon group that has no aromaticity.

Examples of the aliphatic hydrocarbon group as a divalent hydrocarbon group for Ya⁰¹ include a linear or branched group and a group containing a ring in the structure.

The aliphatic hydrocarbon group may be saturated or unsaturated, but is preferably saturated.

As Ya⁰¹, the above-described divalent hydrocarbon groups bonded to each other through an ether bond, a urethane bond, a sulfide bond, or an amide bond may be exemplified.

The linear or branched aliphatic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—]. Among these, a methylene group [—CH₂—], an ethylene group [—(CH₂)₂—], or a trimethylene group [—(CH₂)₃-] is preferable.

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

Examples of the aliphatic hydrocarbon group containing a ring in the structure thereof include alicyclic hydrocarbon groups (groups in which two hydrogen atoms have been removed from an aliphatic hydrocarbon ring), groups in which this type of alicyclic hydrocarbon group is bonded to the terminal of a linear or branched aliphatic hydrocarbon group, or groups in which this type of alicyclic hydrocarbon group is interposed within the chain of a linear or branched aliphatic hydrocarbon group. Examples of the linear or branched aliphatic hydrocarbon group include the same aliphatic hydrocarbon groups as those described above.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic alicyclic hydrocarbon group, a group in which two hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable, and the polycycloalkane preferably has 7 to 12 carbon atoms. Specific examples of the polycycloalkane include adamantane, norbornane, isobornane, tricyclodecane and tetracyclododecane.

The linear or branched aliphatic hydrocarbon group may or may not have a substituent. Examples of the substituent include an alkyl group, an alkoxy group, a halogen atom, a halogenated alkyl group, a hydroxyl group and a carbonyl group.

Examples of the alkyl group as a substituent include an alkyl group having 1 to 5 carbon atoms, and more specific examples thereof include a methyl group, an ethyl group, a propyl group, an n-butyl group and a tert-butyl group.

Examples of the alkoxy group as a substituent include an alkoxy group having 1 to 5 carbon atoms, and specific examples thereof include a methoxy group, an ethoxy group, an n-propoxy group, an iso-propoxy group, an n-butoxy group, and a tert-butoxy group. Among these, a methoxy group or an ethoxy group is preferable.

Examples of the halogen atom as a substituent include a fluorine atom, a chlorine atom, a bromine atom, and an iodine atom.

Examples of the halogenated alkyl group as the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. Examples of the substituent containing a hetero atom include —O—, —C(═O)—O—, —S—, —S(═O)₂—, and —S(═O)₂—O—.

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. Examples of the linear or branched aliphatic hydrocarbon group include the same aliphatic hydrocarbon groups as those described above.

The cyclic aliphatic hydrocarbon group preferably has 3 to 20 carbon atoms, and more preferably 3 to 12 carbon atoms.

Specific examples of the cyclic aliphatic hydrocarbon group are the same as those described above.

The cyclic aliphatic hydrocarbon group may or may not have a substituent. Examples of the substituents are the same as those described above.

### [Aromatic Hydrocarbon Group]

The aromatic hydrocarbon group is a hydrocarbon group having an aromatic ring.

The aromatic hydrocarbon group as the divalent hydrocarbon group for Ya⁰¹ preferably has 3 to 30 carbon atoms, more preferably 5 to 30 carbon atoms, still more preferably 5 to 20 carbon atoms, still more preferably 6 to 15 carbon atoms, and most preferably 6 to 10 carbon atoms. Here, the number of carbon atoms within a substituent(s) is not included in the number of carbon atoms of the aromatic hydrocarbon group.

Specific examples of the aromatic ring included in the aromatic hydrocarbon group include aromatic hydrocarbon rings such as benzene, biphenyl, fluorene, naphthalene, anthracene and phenanthrene; and aromatic heterocycles in which part of the carbon atoms constituting the aforementioned aromatic hydrocarbon ring has been substituted with a hetero atom. Examples of the hetero atom in the aromatic heterocycle include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atoms, more preferably 1 or 2 carbon atoms, and most preferably 1 carbon atom.

Specific examples of the aromatic hydrocarbon group as a divalent hydrocarbon group are the same as those described above.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of the substituent include an alkyl group, an alkoxy group, a halogen atom, a halogenated alkyl group and a hydroxyl group.

The alkyl group as the substituent is preferably an alkyl group of 1 to 5 carbon atoms, and a methyl group, an ethyl group, a propyl group, an n-butyl group or a tert-butyl group is particularly desirable.

As the alkoxy group, the halogen atom and the halogenated alkyl group for the substituent, the same groups as the aforementioned substituent groups for substituting a hydrogen atom within the cyclic aliphatic hydrocarbon group can be used.

### (Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

In the case where Ya⁰¹ represents a divalent linking group containing a hetero atom, preferable examples of the linking group include —O—, —C(═O)—O—, —C(═O)—, —O—C(═O)—O—, —C(═O)—NH—, —NH—, —NH—C(═NH)— (wherein H may be substituted with a substituent such as an alkyl group or an acyl group), —S—, —S(═O)₂—, —S(═O)₂—O—, a group represented by general formula —Y²¹—O—Y²²—, —Y²¹—O—, —Y²¹—C(═O)—O—, —C(═O)—O—Y²¹, —[Y²¹—C(═O)—O]_{m′}—Y²²— or —Y²¹—O—C(═O)—Y²²— [in the formulas, Y²¹ and Y²² each independently represents a divalent hydrocarbon group which may have a substituent, and O represents an oxygen atom; and m′ represents an integer of 0 to 3.

In a case where the divalent linking group containing a hetero atom represents —C(═O)—NH—, —NH—, or —NH—C(═NH)—, H may be substituted with a substituent such as an alkyl group or an acyl group. The substituent (an alkyl group, an acyl group or the like) preferably has 1 to 10 carbon atoms, more preferably 1 to 8 carbon atoms, and most preferably 1 to 5 carbon atoms.

In formulas —Y²¹—O—Y²²—, —Y²¹—O—, —Y²¹—C(═O)—O—, —C(═O)—O—Y²¹, —[Y²¹—C(═O)—O]_{m′}—Y²²— and —Y²¹—O—C(═O)—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

Y²¹ is preferably a linear aliphatic hydrocarbon group, more preferably a linear alkylene group, still more preferably a linear alkylene group of 1 to 5 carbon atoms, and most preferably a methylene group or ethylene group.

Y²² is preferably a linear or branched aliphatic hydrocarbon group, and is more preferably a methylene group, ethylene group or alkylmethylene group. The alkyl group within the alkylmethylene group is preferably a linear alkyl group of 1 to 5 carbon atoms, more preferably a linear alkyl group of 1 to 3 carbon atoms, and most preferably a methyl group.

In the group represented by formula —[Y²¹—C(═O)—O]_{m′}—Y²²—, m′ represents an integer of 0 to 3, and is preferably an integer of 0 to 2, more preferably 0 or 1, and most preferably 1. In other words, it is particularly desirable that the group represented by the formula —[—Y²¹—C(═O)—O]_{m′}—Y²²— be a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the present embodiment, Ya⁰¹ is preferably a linear or branched alkylene group, and more preferably a methylene group [—CH₂—], an ethylene group [—(CH₂)₂-] or a trimethylene group [—(CH₂)₃—]

In general formula (a0-1), Ra⁰¹ represents a hydrocarbon group which may have a substituent.

Examples of the hydrocarbon group for Ra⁰¹ include the aliphatic hydrocarbon group and the monovalent group obtained by adding one hydrogen atom to an aromatic hydrocarbon group that are exemplified in the description of the divalent linking group for Ya⁰¹ described above.

### [Aliphatic Hydrocarbon Group]

As the hydrocarbon group for Ra⁰¹, a linear or branched aliphatic hydrocarbon group is preferable, and the linear or branched aliphatic hydrocarbon group preferably has 1 to 10 carbon atoms, more preferably 1 to 6 carbon atoms, and still more preferably 1 to 4 carbon atoms.

As the linear aliphatic hydrocarbon group, a linear alkyl group is preferable. Specific examples thereof include a methyl group, an ethyl group, a propyl group, a butyl group, a pentyl group, a hexyl group, a heptyl group, an octyl group, a nonyl group and a decyl group, and a methyl group, an ethyl group, a propyl group or a butyl group is particularly preferable As the branched aliphatic hydrocarbon group, a branched alkyl group is preferable, and more specifically, the branched aliphatic hydrocarbon group preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The hydrocarbon group for Ra⁰¹ may be a cyclic aliphatic hydrocarbon group.

The cyclic aliphatic hydrocarbon group may be either a polycyclic group or a monocyclic group. As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one hydrogen atom has been removed from a polycycloalkane is preferable, and the polycycloalkane preferably has 7 to 12 carbon atoms. Specific examples of the polycycloalkane include adamantane, norbornane, isobomane, tricyclodecane and tetracyclododecane.

Examples of the substituent which Ra⁰¹ may have include an alkyl group, an alkoxy group, a halogen atom, a halogenated alkyl group, a hydroxyl group and a carbonyl group.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

Examples of the halogenated alkyl group as the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. As the substituent containing a hetero atom, —O—, —C(═O)—O—, —S—, —S(═O)₂— or —S(═O)₂—O— is preferable.

Among them, a hydroxyl group is preferable as a substituent which Ra⁰¹ may have.

In general formula (a0-1), Ra⁰² represents a hydroxyl group or a hydrocarbon group having 1 to 6 carbon atoms which may have a substituent. Examples of the hydrocarbon group having 1 to 6 carbon atoms include a linear or branched alkyl group, and specific examples thereof include a methyl group, an ethyl group, a propyl group, a butyl group, a pentyl group, a hexyl group, a 1-methylethyl group, a 1-methylpropyl group, a 2-methylpropyl group, a 1-methylbutyl group, a 2-methylbutyl group and a 3-methylbutyl group.

The hydrocarbon group having 1 to 6 carbon atoms for Ra⁰² preferably has a substituent, and examples of the substituent include the same groups as those described as the substituent which the above-mentioned Ra⁰¹ may have.

In general formula (a0-1), n⁰¹ represents an integer of 0 to 5. In general formula (a0-1), when n⁰¹ is 0, Ra⁰¹ is preferably a hydrocarbon group having a hydroxyl group.

The group represented by general formula (a0-1) is preferably a group represented by any one of the general formulas (a0-1-1) to (a0-1-4).

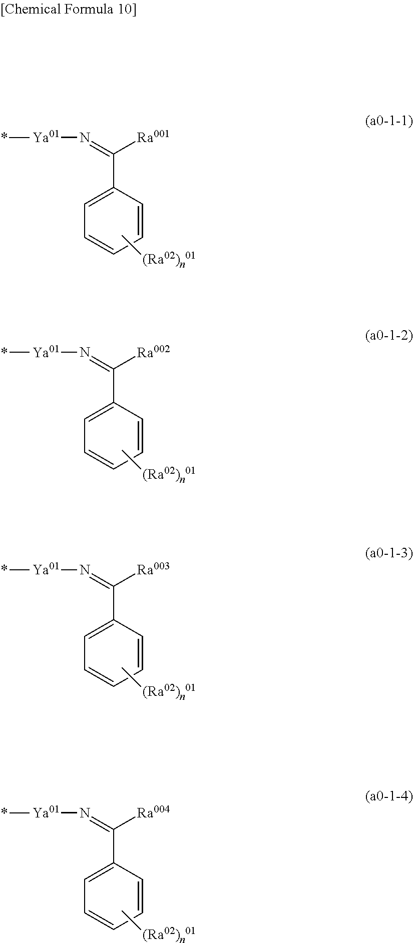

[In the formulas (a0-1-1) to (a0-1-4), Ya⁰¹ represents a divalent linking group; Ra⁰⁰¹ represents a linear hydrocarbon group which may have a substituent; Ra⁰⁰² represents a branched hydrocarbon group which may have a substituent; Ra⁰⁰³ represents an aromatic hydrocarbon group which may have a substituent; Ra⁰⁰⁴ represents a cyclic aliphatic hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond with respect to the silica base material.]

In the general formulas (a0-1-1) to (a0-1-4), Ya⁰¹, Ra⁰² and n⁰¹ are the same as defined above.

### [Ra⁰⁰¹]

Ra⁰⁰¹ is a linear hydrocarbon group which may have a substituent, and is preferably a linear aliphatic hydrocarbon group. The aliphatic hydrocarbon group preferably has 1 to 10 carbon atoms, more preferably 1 to 6 carbon atoms, and still more preferably 1 to 4 carbon atoms.

As the linear aliphatic hydrocarbon group, a linear alkyl group is preferable. Specific examples thereof include a methyl group, an ethyl group, a propyl group, a butyl group, a pentyl group, a hexyl group, a heptyl group, an octyl group, a nonyl group and a decyl group, and a methyl group, an ethyl group, a propyl group or a butyl group is particularly preferable.

### [Ra⁰⁰²]

Ra⁰⁰² is a branched hydrocarbon group which may have a substituent, and is preferably a branched aliphatic hydrocarbon group. As the branched aliphatic hydrocarbon group, a branched alkyl group is preferable, and more specifically, the branched aliphatic hydrocarbon group preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

### [Ra⁰⁰³]

Ra⁰⁰³ is an aromatic hydrocarbon group which may have a substituent. Specific examples of the aromatic ring included in the aromatic hydrocarbon group for Ra⁰⁰³ include aromatic hydrocarbon rings such as benzene, biphenyl, fluorene, naphthalene, anthracene and phenanthrene, among which benzene is preferable.

### [Ra⁰⁰⁴]

Ra⁰⁰⁴ is a cyclic aliphatic hydrocarbon group which may have a substituent and may be either a polycyclic group or a monocyclic group. As the monocyclic aliphatic hydrocarbon group, a monocycloalkane having 3 to 6 carbon atoms can be mentioned, and specific examples thereof include cyclopentane and cyclohexane. As the polycyclic alicyclic hydrocarbon group, a group in which one hydrogen atom has been removed from a polycycloalkane is preferable, and the polycycloalkane preferably has 7 to 12 carbon atoms. Specific examples of the polycycloalkane include adamantane, norbornane, isobornane, tricyclodecane and tetracyclododecane.

Examples of the substituent which Ra⁰⁰¹ to Ra⁰⁰⁴ may have include the same groups as those described as the substituent which the above-mentioned Ra⁰¹ may have.

Specific examples of the group represented by general formula (a0-1-1) are shown below. In the following formulas, Ya⁰¹ is the same as defined above, and the symbol “*” represents a valence bond.

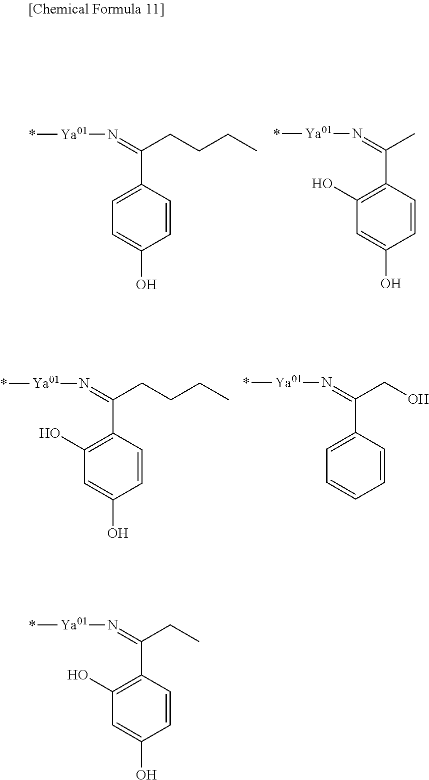

Specific examples of the group represented by general formula (a0-1-2) are shown below. In the following formulas, Ya⁰¹ is the same as defined above, and the symbol “*” represents a valence bond.

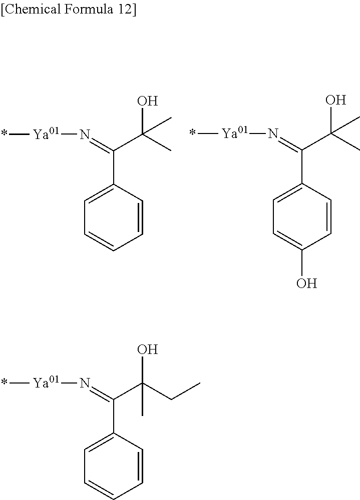

Specific examples of the group represented by general formula (a0-1-3) are shown below. In the following formulas, Ya⁰¹ is the same as defined above, and the symbol “*” represents a valence bond.

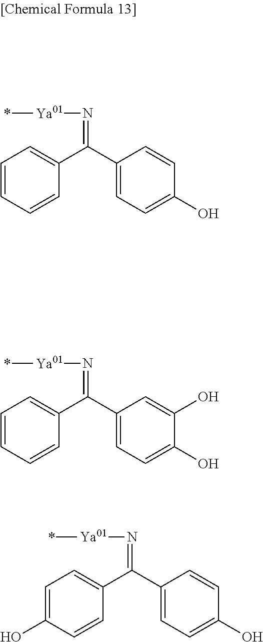

Specific examples of the group represented by general formula (a0-1-4) are shown below. In the following formulas, Ya⁰¹ is the same as defined above, and the symbol “*” represents a valence bond.

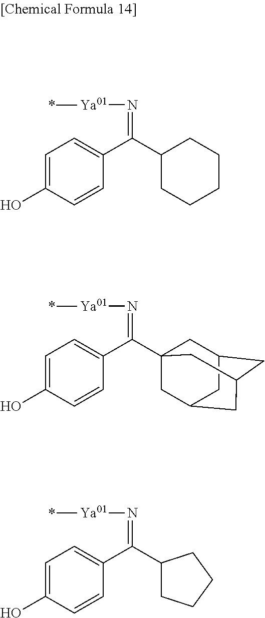

The filtration material of the present embodiment can be obtained, for example, in accordance with the method described in Non-Patent Document (A. Goswami et al., Anal. Chimi. Acta 2002 454, 229-240), by reacting a compound represented by general formula (a0) with a silica base material modified with an amino group as shown in the following Scheme. 1.

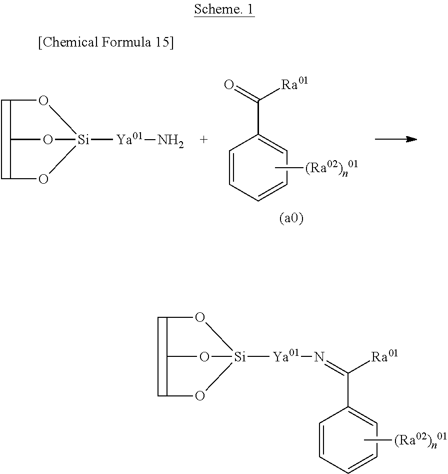

[In Scheme. 1, Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; and n⁰¹ represents an integer of 0 to 5.]

In Scheme. 1, Ya⁰¹, Ra⁰¹, Ra⁰² and n⁰¹ are the same as defined above.

The present embodiment further provides a filtration material characterized by using a porous base material having a group represented by the above general formula (a0-1).

As the porous base material having a group represented by the above general formula (a0-1), for example, it is also possible to adopt those obtained by using a normal filtering material as a material which is described in Japanese Unexamined Patent Application, First Publication No. 2000-281739 as an example of a filtering material used in a functional filtering material, and introducing a group represented by the above general formula (a0-1) thereto.

In the present embodiment, the silica base material is a copolymer of an alkoxysilane having two or more functional groups, and it is preferable to use a copolymer having a partial structure represented by the following general formulas (p-1) and (p-3) (hereinafter, sometimes referred to as “copolymer 1”).

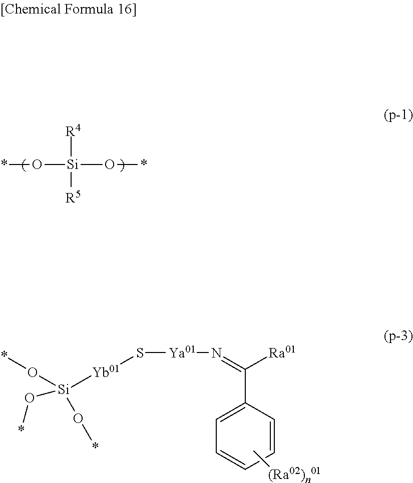

[In the formulas, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In the present description and claims, an alkoxysilane having two or more functional groups refers to an alkoxysilane compound represented by SiR^{x}ₙ[OR^{Y}]₄₋ₙ (R^{x} represents a hydrocarbon group, and R^{Y} represents an alkyl group), where n is equal to or less than 2.

In general formula (p-1), R⁴ and R⁵ represent a hydrocarbon group which may have a substituent.

The hydrocarbon group for R⁴ and R⁵ may be either an aliphatic hydrocarbon group or an aromatic hydrocarbon group. An “aliphatic hydrocarbon group” refers to a hydrocarbon group that has no aromaticity.

The aliphatic hydrocarbon group as the hydrocarbon group may be saturated or unsaturated, and is preferably saturated in general.

### [Aliphatic Hydrocarbon Group]

As specific examples of the aliphatic hydrocarbon group, a linear or branched aliphatic hydrocarbon group, or an aliphatic hydrocarbon group containing a ring in the structure thereof can be given.

The linear or branched aliphatic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkyl group is preferable, and an alkyl group having 1 to 5 carbon atoms is preferable, and specific examples thereof include a methyl group, an ethyl group, a propyl group, an n-butyl group and a tert-butyl group. Among them, R⁴ and R⁵ are preferably methyl groups.

Specific examples of the branched aliphatic hydrocarbon group include an isopropyl group, an isobutyl group, a tert-butyl group, an isopentyl group, a neopentyl group, a 1,1-dimethylethyl group, a 1,1-diethylpropyl group, a 2,2-dimethylpropyl group and a 2,2-dimethylbutyl group.

The alicyclic hydrocarbon group may be either a monocyclic group or a polycyclic group. As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one hydrogen atom has been removed from a polycycloalkane is preferable, and the polycycloalkane preferably has 7 to 12 carbon atoms. Specific examples of the polycycloalkane include adamantane, norbornane, isobomane, tricyclodecane and tetracyclododecane.

### [Aromatic Hydrocarbon Group]

The aromatic hydrocarbon group is a hydrocarbon group having an aromatic ring.

The aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms within a substituent(s) is not included in the number of carbon atoms of the aromatic hydrocarbon group.

Specific examples of the aromatic ring included in the aromatic hydrocarbon group include aromatic hydrocarbon rings such as phenyl, biphenyl, fluorene, naphthalene, anthracene and phenanthrene; and aromatic heterocycles in which part of the carbon atoms constituting the aforementioned aromatic hydrocarbon ring has been substituted with a hetero atom. Examples of the hetero atom in the aromatic heterocycle include an oxygen atom, a sulfur atom and a nitrogen atom.

### [Substituent]

Examples of the substituent which the hydrocarbon group for R⁴ and R⁵ may have include an alkyl group, an alkoxy group, a halogen atom, a halogenated alkyl group, a hydroxyl group, a carbonyl group and a nitro group.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

Examples of the halogenated alkyl group as the substituent include a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

Further, R⁴ and R⁵ may be a hydroxyl group, and one of R⁴ and R⁵ is preferably a hydroxyl group.

Furthermore, one of R⁴ and R⁵ may be bonded to another silicon atom in the alkoxysilane copolymer to form a crosslinked structure.

In formula (p-3), Ya⁰¹ and Yb⁰¹ each independently represent a divalent linking group, Ra⁰¹ is a hydrocarbon group which may have a substituent, Ra⁰² is a hydroxyl group or a hydrocarbon group having 1 to 6 carbon atoms which may have a substituent, and n⁰¹ is an integer of 0 to 5.

In formula (p-3), the divalent linking group for Ya⁰¹ and Yb⁰¹ is not particularly limited, and preferred examples thereof include a divalent hydrocarbon group which may have a substituent and a divalent linking group containing a hetero atom. The description of the divalent linking group for Ya⁰¹ and Yb⁰¹ in formula (p-3) is the same as the description of the divalent linking group for Ya⁰¹ in general formula (a0-1).

In general formula (p-3), Ra⁰¹ represents a hydrocarbon group which may have a substituent.

The description of Ra⁰¹ in general formula (p-3) is the same as the description of Ra⁰¹ in general formula (a0-1).

In general formula (p-3), Ra⁰² represents a hydroxyl group or a hydrocarbon group having 1 to 6 carbon atoms which may have a substituent.

The description of Ra⁰² in general formula (p-3) is the same as the description of Ra⁰² in general formula (a0-1).

The partial structures represented by general formulas (p-1) and (p-3) are bonded at an arbitrary position in the valence bond portion represented by the symbol “*”, and may further have an arbitrary substituent between the valence bonds.

The partial structures represented by general formulas (p-1) and (p-3) may be bonded randomly or may be bonded in a block form.

In general formula (p-3), n⁰¹ is an integer of 0 to 5. In general formula (p-3), when n⁰¹ is 0, Ra⁰¹ is preferably a hydrocarbon group having a hydroxyl group.

The group represented by general formula (p-3) is preferably a group represented by general formula (p-3-1) or (p-3-2).

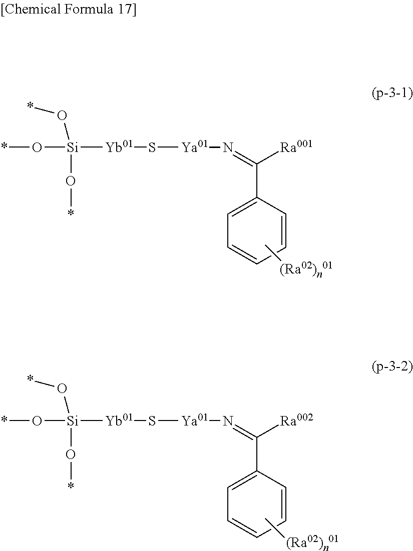

[In formula (p-3-1) or (p-3-2), Ya⁰¹ and Yb⁰¹ each independently represent a divalent linking group; Ra⁰⁰¹ represents a linear hydrocarbon group which may have a substituent; Ra⁰⁰² represents a branched hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In general formulas (p-3-1) and (p-3-2), Yb⁰¹, Ya⁰¹, Ra⁰², n⁰¹ are the same as defined above.

Ra⁰⁰¹ is a linear hydrocarbon group which may have a substituent, and is preferably a linear aliphatic hydrocarbon group. The aliphatic hydrocarbon group preferably has 1 to 10 carbon atoms, more preferably 1 to 6 carbon atoms, and still more preferably 1 to 4 carbon atoms.

As the linear aliphatic hydrocarbon group, a linear alkyl group is preferable. Specific examples thereof include a methyl group, an ethyl group, a propyl group, a butyl group, a pentyl group, a hexyl group, a heptyl group, an octyl group, a nonyl group and a decyl group, and a methyl group, an ethyl group, a propyl group or a butyl group is particularly preferable.

Ra⁰⁰² is a branched hydrocarbon group which may have a substituent, and is preferably a branched aliphatic hydrocarbon group. As the branched aliphatic hydrocarbon group, a branched alkyl group is preferable, and more specifically, the branched aliphatic hydrocarbon group preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

Examples of the substituent which Ra⁰⁰¹ or Ra⁰⁰² may have include the same groups as those described as the substituent which the above-mentioned Ra⁰¹ may have.

Specific examples of the group represented by general formula (p-3-1) are shown below. In the following formulas, Yb⁰¹ and Ya⁰¹ are the same as defined above, and the symbol “*” represents a valence bond.

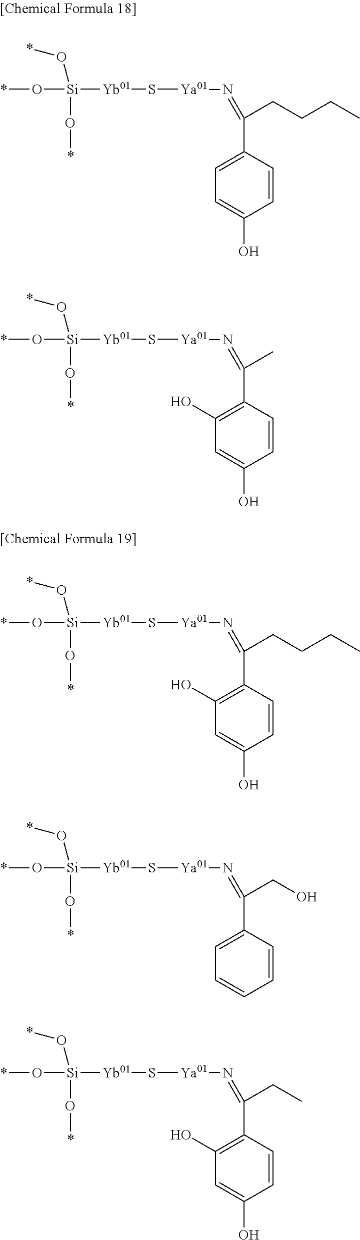

Specific examples of the group represented by general formula (p-3-2) are shown below. In the following formulas, Yb⁰¹ and Ya⁰¹ are the same as defined above, and the symbol “*” represents a valence bond.

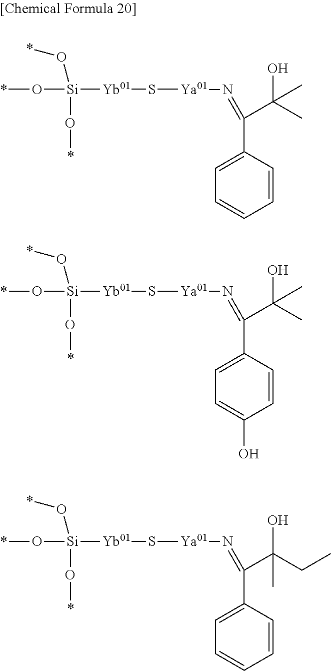

In the present embodiment, the above copolymer 1 is a copolymer of an alkoxysilane having two or more functional groups, and if it has a partial structure represented by the above general formulas (p-1) and (p-3), it may have a trifunctional partial structure represented by the following general formula (p-6) or a tetrafunctional partial structure represented by the following general formula (p-7). In the following formulas, R⁴ is the same as defined above, and the symbol “*” represents a valence bond.

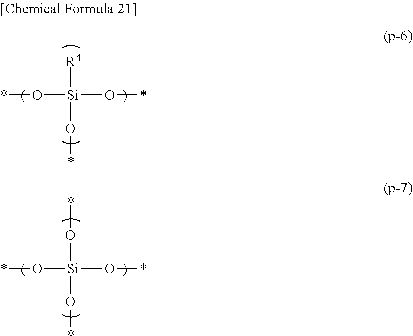

Alternatively, pentafunctional or higher functional alkoxysilanes may be used. Examples of such alkoxysilanes include bistrimethoxysilylmethane, bistrimethoxysilylethane and bistrimethoxysilylhexane.

In the present embodiment, the copolymer 1 has a partial structure of a bifunctional alkoxysilane represented by general formula (p-1) and a partial structure of a trifunctional alkoxysilane represented by general formula (p-3), and exhibits nonhydrolyzability within the molecule. Therefore, a copolymer having both high flexibility and high porosity can be obtained.

For this reason, for example, when the copolymer 1 is used as a filtration material in the present embodiment, a filling operation into a column or the like is facilitated. Further, since the copolymer 1 has a high porosity, it can be made to have a high specific surface area and excellent solvent absorbency.

In the present embodiment, the copolymer 1 can be easily obtained via a metal free step from a starting composition including both a bifunctional alkoxysilane represented by general formula (p-1) and a trifunctional alkoxysilane represented by general formula (p-3). Therefore, it can be suitably used as a filtration material for removing metal impurities such as metal particles and metal ions.

As described above, in the present embodiment, the starting composition including both the bifunctional alkoxysilane represented by general formula (p-1) and the trifunctional alkoxysilane represented by general formula (p-3) forms a Si—O bond network by a copolymerization reaction, thereby obtaining the copolymer 1. At this time, by adjusting the amount of the trifunctional alkoxysilane added, the ratio of the bifunctional alkoxysilane and the trifunctional alkoxysilane can be appropriately adjusted. By adjusting the ratio of the bifunctional alkoxysilane and the trifunctional alkoxysilane, the pore size and flexibility of the copolymer can be adjusted.

In the present embodiment, the compounding ratios of the partial structures represented by general formulas (p-1) and (p-3) are not particularly limited in the copolymer 1, but the abundance ratios of the alkoxysilanes in the copolymer are preferably 10 to 90%, respectively.

In the present embodiment, the compounding ratio of the partial structure represented by general formula (p-1) in the copolymer is preferably 10 to 90%, more preferably 20 to 80%, and particularly preferably 30 to 50%.

In the present embodiment, the compounding ratio of the partial structure represented by general formula (p-3) in the copolymer is preferably 10 to 90%, more preferably 20 to 80%, and particularly preferably 50 to 70%.

The upper limit value and the lower limit value of the compounding ratios of the partial structures represented by general formulas (p-1) and (p-3) in the copolymer can be arbitrarily combined.

In the copolymer of the present embodiment, the compounding ratios of the partial structures represented by general formulas (p-1) and (p-3) may be appropriately adjusted according to the desired characteristics. For example, by adjusting the compounding ratio of the partial structure represented by general formula (p-1), the flexibility of the copolymer can be controlled, and by adjusting the compounding ratio of the partial structure represented by general formula (p-3), the porosity of the copolymer can be controlled.

Further, from the viewpoint of making the pore size of the copolymer smaller, it is preferable that the amount of the trifunctional alkoxysilane added is larger than the amount of the bifunctional alkoxysilane added.

In the present embodiment, it is preferable to use a copolymer having a partial structure represented by the following general formulas (p-1) and (p-5) (hereinafter, sometimes referred to as “copolymer 2”) which is a copolymer of an alkoxysilane having two or more functional groups as a silica base material.

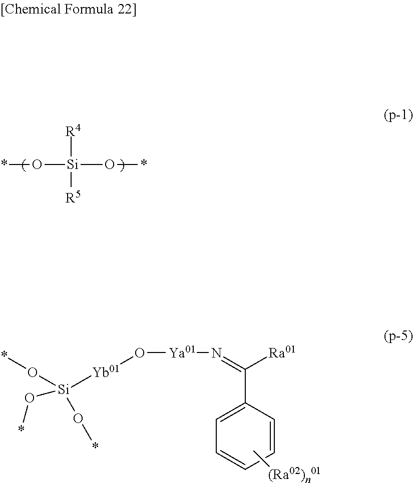

[In the formulas, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In the above formula, R⁴, R⁵, Ya⁰¹, Yb⁰¹, Ra⁰¹, Ra⁰² and n⁰¹ are the same as defined above.

The group represented by general formula (p-5) is preferably a group represented by general formula (p-5-1) or (p-5-2).

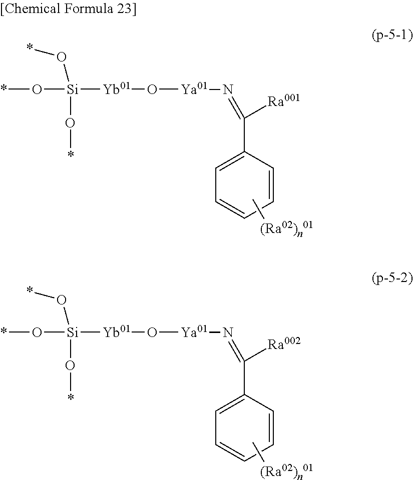

[In formulas (p-5-1) and (p-5-2), Ya⁰¹ and Yb⁰¹ each independently represent a divalent linking group; Ra⁰⁰¹ represents a linear hydrocarbon group which may have a substituent; Ra⁰⁰² represents a branched hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In general formulas (p-5-1) and (p-5-2), Ya⁰¹, Yb⁰¹, Ra⁰², n⁰¹, Ra⁰⁰¹ and Ra⁰⁰² are the same as defined above.

Specific examples of the group represented by general formula (p-5-1) are shown below. In the following formulas, Ya⁰¹ and Yb⁰¹ are the same as defined above, and the symbol “*” represents a valence bond.

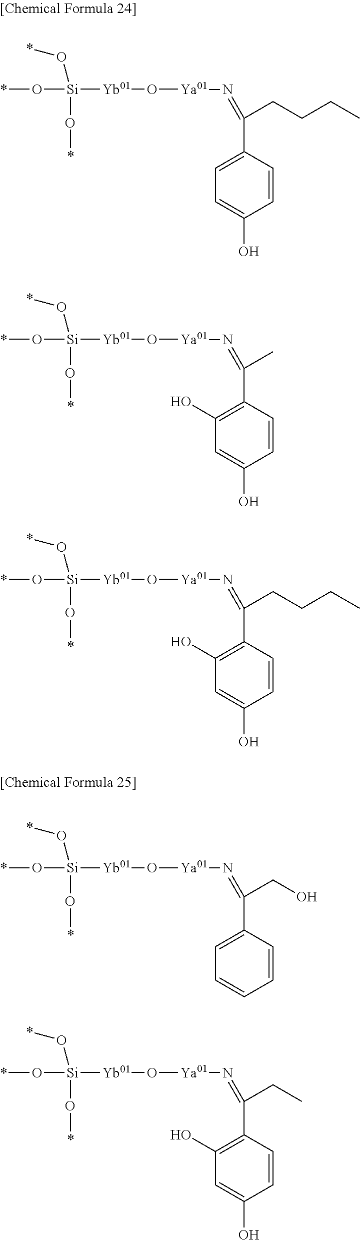

Specific examples of the group represented by general formula (p-5-2) are shown below. In the following formulas, Ya⁰¹ and Yb⁰¹ are the same as defined above, and the symbol “*” represents a valence bond.

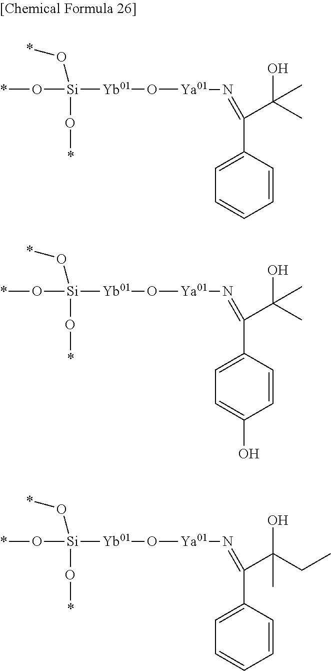

In the present embodiment, the above copolymer 2 is a copolymer of an alkoxysilane having two or more functional groups, and if it has a partial structure represented by the above general formulas (p-1) and (p-5), it may have a trifunctional partial structure represented by the following general formula (p-6) or a tetrafunctional partial structure represented by the following general formula (p-7). In the following formulas, R⁴ is the same as defined above, and the symbol “*” represents a valence bond.

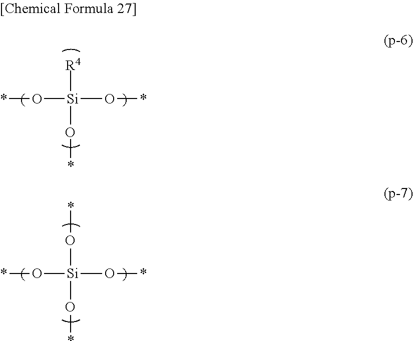

Alternatively, pentafunctional or higher functional alkoxysilanes may be used. Examples of such alkoxysilanes include bistrimethoxysilylmethane, bistrimethoxysilylethane and bistrimethoxysilylhexane.

In the present embodiment, the copolymer 2 has a partial structure of a bifunctional alkoxysilane represented by general formula (p-1) and a partial structure of a trifunctional alkoxysilane represented by general formula (p-5), and exhibits nonhydrolyzability within the molecule. Therefore, a copolymer having both high flexibility and high porosity can be obtained.

For this reason, for example, when the copolymer 2 of the present embodiment is used as a filtration material, a filling operation into a column or the like is facilitated. Further, since the copolymer 2 has a high porosity, it can be made to have a high specific surface area and excellent solvent absorbency.

In the present embodiment, the copolymer 2 can be easily obtained via a metal free step from a starting composition including both a bifunctional alkoxysilane represented by general formula (p-1) and a trifunctional alkoxysilane represented by general formula (p-5). Therefore, it can be suitably used as a filtration material for removing metal impurities such as metal particles and metal ions.

As described above, in the present embodiment, the starting composition including both the bifunctional alkoxysilane represented by general formula (p-1) and the trifunctional alkoxysilane represented by general formula (p-5) forms a Si—O bond network by a copolymerization reaction, thereby obtaining the copolymer 2. At this time, by adjusting the amount of the trifunctional alkoxysilane added, the ratio of the bifunctional alkoxysilane and the trifunctional alkoxysilane can be appropriately adjusted. By adjusting the ratio of the bifunctional alkoxysilane and the trifunctional alkoxysilane, the pore size and flexibility of the copolymer can be adjusted.

In the present embodiment, the compounding ratios of the partial structures represented by general formulas (p-1) and (p-5) are not particularly limited in the copolymer 2, but the abundance ratios of the alkoxysilanes in the copolymer are preferably 10 to 90%, respectively.

In the present embodiment, the compounding ratio of the partial structure represented by general formula (p-1) in the copolymer is preferably 10 to 90%, more preferably 20 to 80%, and particularly preferably 30 to 50%.

In the present embodiment, the compounding ratio of the partial structure represented by general formula (p-5) in the copolymer is preferably 10 to 90%, more preferably 20 to 80%, and particularly preferably 50 to 70%.

The upper limit value and the lower limit value of the compounding ratio of the partial structures represented by general formulas (p-1) and (p-5) in the copolymer can be arbitrarily combined.

In the copolymer of the present embodiment, the compounding ratios of the partial structures represented by general formulas (p-1) and (p-5) may be appropriately adjusted according to the desired characteristics. For example, by adjusting the compounding ratio of the partial structure represented by general formula (p-1), the flexibility of the copolymer can be controlled, and by adjusting the compounding ratio of the partial structure represented by general formula (p-5), the porosity of the copolymer can be controlled.

Further, from the viewpoint of making the pore size of the copolymer smaller, it is preferable that the amount of the trifunctional alkoxysilane added is larger than the amount of the bifunctional alkoxysilane added.

### [Production Method of Copolymer 1]

The copolymer 1 can be produced by including: a step A of reacting a compound represented by the following general formula (1) with a compound represented by the following general formula (2) to obtain a copolymer (A) having a partial structure represented by the following general formulas (p-1) and (p-2); a step B of modifying the copolymer (A) obtained in the step A to obtain a copolymer (B) having a partial structure represented by the following general formula (p-B-1); and a step C of modifying the copolymer (B) obtained in the step B to obtain a copolymer (C) having a partial structure represented by the following general formulas (p-3) and (p-1).

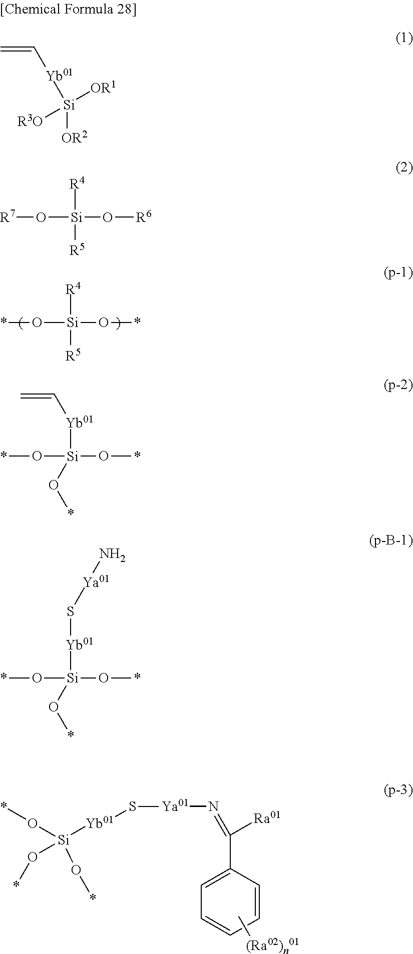

[In the formulas, R¹ to R³ and R⁶ to R⁷ each independently represent an alkyl group having 1 to 5 carbon atoms, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In the above general formulas (1), (2), (p-1), (p-2), (p-B-1) and (p-3), R⁴, R⁵, Ya⁰¹, Yb⁰¹, Ra⁰¹, Ra⁰² and n⁰¹ are the same as defined above.

R¹ to R³ and R⁶ to R⁷ each independently represent an alkyl group having 1 to 5 carbon atoms, and examples of the alkyl group having 1 to 5 carbon atoms include the same alkyl groups having 1 to 5 carbon atoms as those described above for R⁴ and R⁵.

### [Step A]

Step A is a step of reacting a compound represented by the above general formula (1) with a compound represented by the above general formula (2) to obtain a copolymer (A) having a partial structure represented by the above general formulas (p-1) and (p-2).

In Step A, it is preferable to add a bifunctional alkoxysilane represented by the general formula (2) and a trifunctional alkoxysilane represented by the general formula (1) to an acidic solution containing a surfactant and a hydrolyzable compound to obtain the copolymer (A) by a sol-gel reaction.

Hereinafter, preferred embodiments of Step A will be described.

First, a compound represented by general formula (1) and a compound represented by general formula (2) are hydrolyzed using an acidic solution to solate the silicon compounds. As the acid of the acidic solution, carboxylic acids can be exemplified, and acetic acid, formic acid, propionic acid, oxalic acid and malonic acid are preferable, and acetic acid is more preferable. The concentration of the acidic solution is preferably from 0.0001 to 0.2 M, and more preferably from 0.002 to 0.1 M.

Examples of the surfactant contained in the acidic solution include a nonionic surfactant and an ionic surfactant, and an ionic surfactant is preferable, and a cationic surfactant is more preferable.

Examples of the cationic surfactant include hexadecyltrimethylammonium chloride and hexadecyltrimethylammonium bromide, and hexadecyltrimethylammonium chloride is preferred.

The above surfactant reduces the difference in the chemical affinity between the solvent in the reaction system and the copolymer (A) when the compound represented by the above general formula (1) and the compound represented by the above general formula (2) form a siloxane network by a hydrolysis/polycondensation reaction while retaining the nonhydrolyzable functional groups such as R⁴ and R⁵ in the general formula (2). By reducing the difference, the pores in the copolymer become finer.

The hydrolyzable compound contained in the acidic solution is for promoting gelation of the produced sol. Examples of the hydrolyzable compound include urea, formamide, N-methylformamide, N,N-dimethylformamide, acetamide, N-methylacetamide, N,N-dimethylacetamide and hexamethylenetetramine, and urea is preferred.

The heating temperature for hydrolyzing the compound represented by the above general formula (1) and the compound represented by the above general formula (2) is preferably from 50 to 200° C., and more preferably from 60 to 100° C.

Next, in order to remove the moisture, acidic solution, surfactant, hydrolyzable compound, unreacted silicon compound material and the like remaining in the gel obtained by the sol-gel reaction, it is preferable to perform solvent exchange using an organic polar solvent.

In Step A, a flexible gel network can be constructed by the networking of Si—O bonds.

It should be noted that a trifunctional compound, a tetrafunctional compound, a tetrafunctional or higher functional compound or the like may be added in the step A in addition to the compound represented by the above general formula (1) and the compound represented by the above general formula (2).

### [Step B]

Step B is a step of modifying the copolymer (A) obtained in the above step A to obtain a copolymer (B) having a partial structure represented by the above general formula (p-B-1).

In the step B, the copolymer (A) obtained in the step A is modified with an amino group. Although the method of modifying with an amino group is not particularly limited, for example, a thiol-ene reaction using a compound represented by the following general formula (b1) can be adopted.

[Chemical Formula 29]

H₂N—Ya⁰¹-SH (b1)

[In the formula, Ya⁰¹ is the same as defined above.]

### [Step C]

Step C is a step of modifying the copolymer (B) obtained in the above step B to obtain a copolymer (C) having a partial structure represented by the above general formulas (p-3) and (p-1).

The step C can be carried out, for example, by reacting the copolymer (B) modified with an amino group with a compound represented by the following general formula (a0) in accordance with the method described in Non-Patent Document (A. Goswami et al., Anal. Chimi. Acta 2002 454, 229-240).

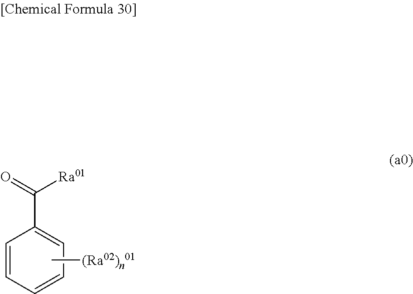

[In the above formula, Ra⁰¹ represents a hydrocarbon group which may have a substituent, Ra⁰² represents a hydroxyl group or a hydrocarbon group having 1 to 6 carbon atoms which may have a substituent, and

n⁰¹ represents an integer of 0 to 5.]

Ra⁰¹, Ra⁰² and n⁰² are the same as defined above.

### [Production Method of Copolymer 2]

The copolymer 2 can be produced by including: a step X of obtaining a copolymer (X) having a partial structure represented by the following general formulas (p-1) and (p-4) by reacting a compound represented by the following general formula (3) with a compound represented by the following general formula (2); a step Y of obtaining a copolymer (Y) having a partial structure represented by the following general formula (p-Y-1) by modifying the copolymer (X) obtained in the step X; and a step Z of obtaining a copolymer (Z) having a partial structure represented by the following general formulas (p-5) and (p-1) by modifying the copolymer (Y) obtained in the step Y.

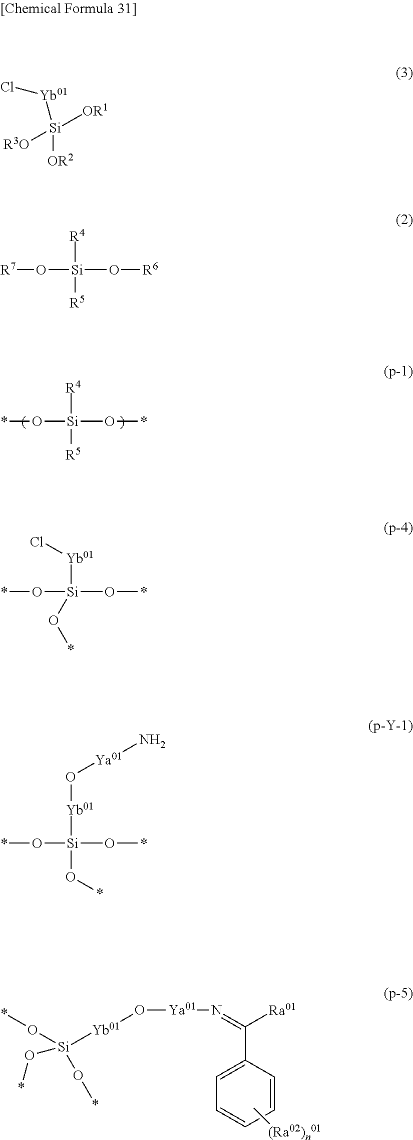

[In the formulas, R¹ to R³ and R⁶ to R⁷ each independently represent an alkyl group having 1 to 5 carbon atoms, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

In the above general formulas (3), (2), (p-1), (p-4), (p-Y-1) and (p-5), R⁴, R⁵, Ya⁰¹, Yb⁰¹, Ra⁰¹, Ra⁰² and n⁰¹ are the same as defined above.

R¹ to R³ and R⁶ to R⁷ each independently represent an alkyl group having 1 to 5 carbon atoms, and examples of the alkyl group having 1 to 5 carbon atoms include the same alkyl groups having 1 to 5 carbon atoms as those described above for R⁴ and R⁵.

### [Step X]

Step X is a step of reacting a compound represented by the above general formula (3) with a compound represented by the above general formula (2) to obtain a copolymer (X) having a partial structure represented by the above general formulas (p-1) and (p-4).

In Step X, it is preferable to add a bifunctional alkoxysilane represented by general formula (2) and a trifunctional alkoxysilane represented by general formula (3) to an acidic solution containing a surfactant and a hydrolyzable compound to obtain the copolymer (X) by a sol-gel reaction.

Hereinafter, preferred embodiments of Step X will be described.

First, a compound represented by general formula (3) and a compound represented by general formula (2) are hydrolyzed using an acidic solution to solate the silicon compounds. As the acid of the acidic solution, carboxylic acids can be exemplified, and acetic acid, formic acid, propionic acid, oxalic acid and malonic acid are preferable, and acetic acid is more preferable. The concentration of the acidic solution is preferably from 0.0001 to 0.2 M, and more preferably from 0.002 to 0.1 M.

Examples of the surfactant contained in the acidic solution include a nonionic surfactant and an ionic surfactant, and an ionic surfactant is preferable, and a cationic surfactant is more preferable.

Examples of the cationic surfactant include hexadecyltrimethylammonium chloride and hexadecyltrimethylammonium bromide, and hexadecyltrimethylammonium chloride is preferred.

The above surfactant reduces the difference in the chemical affinity between the solvent in the reaction system and the copolymer (X) when the compound represented by the above general formula (3) and the compound represented by the above general formula (2) form a siloxane network by a hydrolysis/polycondensation reaction while retaining the nonhydrolyzable functional groups such as R⁴ and R⁵ in general formula (2). By reducing the difference, the pores in the copolymer become finer.

The hydrolyzable compound contained in the acidic solution is for promoting gelation of the produced sol. Examples of the hydrolyzable compound include urea, formamide, N-methylformamide, N,N-dimethylformamide, acetamide, N-methylacetamide, N,N-dimethylacetamide and hexamethylenetetramine, and urea is preferred.

The heating temperature for hydrolyzing the compound represented by the above general formula (3) and the compound represented by the above general formula (2) is preferably from 50 to 200° C., and more preferably from 60 to 100° C.

Next, in order to remove the moisture, acidic solution, surfactant, hydrolyzable compound, unreacted silicon compound material and the like remaining in the gel obtained by the sol-gel reaction, it is preferable to perform solvent exchange using an organic polar solvent.

In step X, a flexible gel network can be constructed by the networking of Si—O bonds.

It should be noted that a trifunctional compound, a tetrafunctional compound, a tetrafunctional or higher functional compound or the like may be added in the step X in addition to the compound represented by the above general formula (3) and the compound represented by the above general formula (2).

### [Step Y]

Step Y is a step of modifying the copolymer (X) obtained in the step X to obtain a copolymer (Y) having a partial structure represented by the above general formula (p-Y-1).

In the step Y, the copolymer (X) obtained in the step X is modified with an amino group. Although the method for modifying with an amino group is not particularly limited, for example, a Williamson ether reaction using an amine alcohol represented by the following general formula (b2) can be adopted.

[Chemical Formula 32]

H₂N—Ya⁰¹-OH (b2)

[In the formula, Ya⁰¹ is the same as defined above.]

### [Step Z]

Step Z is a step of modifying the copolymer (Y) obtained in the step Y to obtain a copolymer (Z) having a partial structure represented by the above general formulas (p-5) and (p-1).

The step Z can be carried out, for example, by reacting the copolymer (Y) modified with an amino group with a compound represented by the following general formula (a0) in accordance with the method described in Non-Patent Document (A. Goswami et al., Anal. Chimi. Acta 2002 454, 229-240).

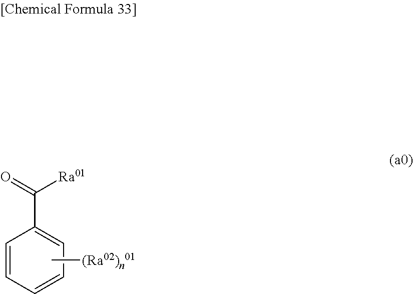

[In the above formula, Ra⁰¹ represents a hydrocarbon group which may have a substituent; Ra⁰² represents a hydroxyl group or a hydrocarbon group having 1 to 6 carbon atoms which may have a substituent; and n⁰¹ represents an integer of 0 to 5.]

Ra⁰¹, Ra⁰² and n⁰¹ are the same as defined above.

### <Organic Solvent>

An organic solvent capable of removing impurities with high removal efficiency by using the filtration material of the present embodiment will be described.

As the organic solvent (hereinafter, sometimes referred to as “component (S)”), known resist solvents to be used in the resist composition can be mentioned.

Examples thereof include lactones such as γ-butyrolactone; ketones such as acetone, methyl ethyl ketone (MEK), cyclohexanone, methyl-n-pentyl ketone (2-heptanone) and methyl isopentyl ketone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and nitrile organic solvents such as dimethylsulfoxide (DMSO) and acetonitrile.

These organic solvents may be used individually as a filtrate, or may be used, as a filtrate, as a mixed solvent containing two or more solvents.

Among them, a mixed solvent with cyclohexanone or cyclohexanone is preferable.

Further, among the mixed solvents, a mixed solvent obtained by mixing PGMEA with a polar solvent is preferable.

### <Resist Composition>

A resist composition capable of removing impurities with high removal efficiency by using the filtration material of the present embodiment will be described.

The resist composition is obtained by dissolving a base material component (A) which exhibits changed solubility in a developing solution under action of acid (hereinafter, referred to as “component (A)”), an acid generator component (B) which generates an acid upon exposure (hereinafter, referred to as “component (B)”), a quencher (acid diffusion control agent) which traps the acid generated from the component (B) or the like upon exposure (hereinafter, referred to as “component (D)”), at least one compound (E) selected from the group consisting of organic carboxylic acids and phosphorus oxo acids and derivatives thereof (hereinafter, referred to as “component (E)”), a fluorine additive (hereinafter, referred to as “component (F)”) or the like in the organic solvent (hereinafter, sometimes referred to as “component (S)”).

When a resist film is formed using the resist composition and the formed resist film is subjected to a selective exposure, acid is generated from the component (B) at exposed portions, and the generated acid acts on the component (A) to change the solubility of the component (A) in a developing solution, whereas the solubility of the component (A) in a developing solution is not changed at unexposed portions, thereby generating difference in solubility in a developing solution between exposed portions and unexposed portions. Therefore, by subjecting the resist film to development, the exposed portions are dissolved and removed to form a positive-tone resist pattern in the case of a positive resist, whereas the unexposed portions are dissolved and removed to form a negative-tone resist pattern in the case of a negative resist.

### <Component (A)>

In the present embodiment, the term “base material component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed.

The organic compound used as the base material component is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. Hereafter, a “resin” refers to a polymer having a molecular weight of 1,000 or more.

As the molecular weight of the polymer, the weight average molecular weight in terms of the polystyrene equivalent value determined by gel permeation chromatography (GPC) is used.

As the component (A), a resin, a low molecular weight compound, or a combination thereof may be used.

The component (A) may exhibit increased solubility in the developing solution under the action of acid, or decreased solubility in the developing solution under the action of acid.

In the present embodiment, the component (A) may be a component that generates acid upon exposure.

The component (A) preferably includes a structural unit (a1) containing an acid decomposable group that exhibits increased polarity by the action of acid, a structural unit (a2) containing a lactone-containing cyclic group (provided that the structural units that fall under the definition of structural unit (a1) are excluded), a structural unit (a3) containing a polar group-containing aliphatic hydrocarbon group (provided that the structural units that fall under the definition of structural units (a1) and (a2) are excluded), a structural unit (a4) containing an acid non-dissociable cyclic group, a structural unit (a5) containing a carbonate-containing cyclic group, or an —SO₂— containing cyclic group, or the like.

(Structural Unit (a1))

The structural unit (a1) is a structural unit containing an acid decomposable group that exhibits increased polarity by the action of acid.

The term “acid decomposable group” refers to a group in which at least a part of the bond within the structure thereof is cleaved by the action of an acid.

Examples of acid decomposable groups that exhibit increased polarity by the action of an acid include groups which are decomposed by the action of an acid to form a polar group.

Examples of the polar group include a carboxy group, a hydroxyl group, an amino group and a sulfo group (—SO₃H). Among these, a polar group containing —OH in the structure thereof (hereafter, sometimes referred to as “OH-containing polar group”) is preferable, a carboxy group or a hydroxyl group is more preferable, and a carboxy group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

Here, the “acid dissociable group” includes:

(i) a group in which the bond between the acid dissociable group and the adjacent atom is cleaved by the action of acid; and

(ii) a group in which one of the bonds is cleaved by the action of acid, and then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in a developing solution changes and, the solubility in an organic developing solution is relatively decreased.

The acid dissociable group is not particularly limited, and any of the groups that have been conventionally proposed as acid dissociable groups for the base resins of chemically amplified resists can be used.

In the component (A), the amount of the structural unit (a1) based on the combined total of all structural units constituting the component (A) is preferably 20 to 80 mol %, more preferably 20 to 75 mol %, and still more preferably 25 to 70 mol %.

(Structural Unit (a2))

The structural unit (a2) is a lactone-containing cyclic group.

When the component (A1) is used for forming a resist film, the lactone-containing cyclic group of the structural unit (a2) is effective in improving the adhesion between the resist film and the substrate.

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The structural unit (a2) of the component (A) may be either a single type of structural unit or a combination of two or more types of structural units.

When the component (A) contains the structural unit (a2), the amount of the structural unit (a2) based on the combined total of all structural units constituting the component (A) is preferably 1 to 80 mol %, more preferably 5 to 70 mol %, still more preferably 10 to 65 mol %, and most preferably 10 to 60 mol %.

(Structural Unit (a3))

The structural unit (a3) is a structural unit containing a polar group-containing aliphatic hydrocarbon group (provided that the structural units that fall under the definition of structural units (a1) and (a2) are excluded).

When the component (A) includes the structural unit (a3), it is presumed that the hydrophilicity of the component (A) is enhanced, thereby contributing to improvement in resolution.

Examples of the polar group include a hydroxyl group, a cyano group, a carboxy group, or a hydroxyalkyl group in which some of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups may be either a polycyclic group or a monocyclic group, and can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

The structural unit (a3) contained within the component (A) may be either a single type of structural unit or a combination of two or more types of structural units.

The amount of the structural unit (a3) within the component (A) based on the combined total of all structural units constituting the component (A) is preferably 5 to 50 mol %, more preferably 5 to 40 mol %, and still more preferably 5 to 25 mol %.

(Structural Unit (a4))

The structural unit (a4) is a structural unit containing an acid non-dissociable cyclic group. When the component (A) includes the structural unit (a4), dry etching resistance of the resist pattern to be formed is improved.

An “acid non-dissociable cyclic group” in the structural unit (a4) refers to a cyclic group which is not dissociated by the action of acid generated from the component (B) upon exposure, and remains in the structural unit.

When the structural unit (a4) is included in the component (A), the amount of the structural unit (a4) based on the combined total of all the structural units that constitute the component (A) is preferably within the range from 1 to 30 mol %, and more preferably from 10 to 20 mol %.

The structural unit (a5) is a structural unit containing an —SO₂— containing cyclic group or a carbonate-containing cyclic group.

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

The —SO₂— containing cyclic group as a cyclic hydrocarbon group for R¹ is particularly preferably a cyclic group containing an —O—SO₂— group within the ring skeleton, namely a cyclic group containing a sultone ring in which the —O—S— within the —O—SO₂— forms a part of the ring skeleton.

The term “carbonate-containing cyclic group” refers to a cyclic group including a ring containing a —O—C(═O)—O— structure (carbonate ring). The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

The structural unit (a5) of the component (A) may be either a single type of structural unit or a combination of two or more types of structural units.

When the component (A) contains the structural unit (a5), the amount of the structural unit (a5) based on the combined total of all structural units constituting the component (A) is preferably 1 to 80 mol %, more preferably 5 to 70 mol %, still more preferably 10 to 65 mol %, and most preferably 10 to 60 mol %.

In the present embodiment, the weight average molecular weight (Mw) (the polystyrene equivalent value determined by gel permeation chromatography) of the component (A) is not particularly limited, but is preferably 1,000 to 50,000, more preferably 1,500 to 30,000, and most preferably 2,000 to 20,000.

In the resist composition of the present embodiment, as the component (A), one type may be used, or two or more types of compounds may be used in combination.

In the resist composition of the present embodiment, the amount of the component (A) may be adjusted in accordance with factors such as the thickness of the resist film that is to be formed.

### <Acid Generator Component; Component (B)>

The component (B) is an acid generator component which generates acid upon exposure.

As the component (B), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators. Among these, it is preferable to use an onium salt acid generator.

When the resist composition contains the component (B), the amount of the component (B) relative to 100 parts by weight of the component (A) is preferably within a range from 0.5 to 60 parts by weight, more preferably from 1 to 50 parts by weight, and still more preferably from 1 to 40 parts by weight. When the amount of the component (B) is within the above-mentioned range, formation of a resist pattern can be satisfactorily performed. Further, by virtue of the above-mentioned range, when each of the components are dissolved in an organic solvent, a uniform solution can be obtained and the storage stability becomes satisfactory.

### <Acid Diffusion Control Agent Component; Component (D)>

The component (D) is an acid diffusion control agent component.

The component (D) functions as an acid diffusion control agent, i.e., a quencher which traps the acid generated from the component (B) and the like upon exposure.

In the present embodiment, the component (D) may be a photodecomposable base (D1) (hereafter, referred to as “component (D1)”) which is decomposed upon exposure and then loses the ability of controlling of acid diffusion, or a nitrogen-containing organic compound (D2) (hereafter, referred to as “component (D2)”) which does not fall under the definition of component (D1).

The amount of the component (D1) relative to 100 parts by weight of the component (A) is preferably within a range from 0.5 to 10.0 parts by weight, more preferably from 0.5 to 8.0 parts by weight, and still more preferably from 1.0 to 8.0 parts by weight. When the amount of the component (D1) is at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and through-put becomes excellent.

### [Component (D2)]

The component (D) may contain a nitrogen-containing organic compound component (hereafter, referred to as component (D2)) which does not fall under the definition of component (D1).

The component (D2) is not particularly limited, as long as it functions as an acid diffusion control agent, and does not fall under the definition of the component (D1). As the component (D2), any of the conventionally known compounds may be selected for use. Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

As the component (D2), one type of compound may be used alone, or two or more types may be used in combination.

The component (D2) is typically used in an amount within a range from 0.01 to 5.0 parts by weight, relative to 100 parts by weight of the component (A). By ensuring that the amount of the component (D2) is within the aforementioned range, the shape of the resist pattern and the post exposure stability of the latent image formed by the pattern-wise exposure of the resist layer are improved.

As the component (D), one type of compound may be used, or two or more types of compounds may be used in combination.

When the resist composition of the present embodiment contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties (such as LWR) of the resist composition are improved. Further, a resist pattern having an excellent shape can be obtained. On the other hand, when the amount of the component (D) is no more than the upper limit of the above-mentioned range, sensitivity can be maintained at a satisfactory level, and through-put becomes excellent.

### <Optional Components>

### [Component (E)]

For the purposes of preventing any deterioration in sensitivity, and improving the resist pattern shape and the post exposure stability of the latent image formed by the pattern-wise exposure of the resist layer, at least one compound (E) (hereinafter referred to as “component (E)”) selected from the group consisting of organic carboxylic acids, and phosphorus oxo acids and derivatives thereof may also be added as an optional component.

As the component (E), one type may be used alone, or two or more types may be used in combination.

The component (E) is typically used in an amount within a range from 0.01 to 5.0 parts by weight, relative to 100 parts by weight of the component (A).

### [Component (F)]

In order to impart water repellency to the resist film, a fluorine additive (hereinafter referred to as “component (F)”) may be contained.

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used.

If desired, other miscible additives can also be added to the resist composition. Examples of such miscible additives include additive resins for improving the performance of the resist film, dissolution inhibitors, plasticizers, stabilizers, colorants, halation prevention agents, and dyes.

By using the filtration material of the present embodiment, it is possible to remove impurities, particularly metal components with high removal efficiency. Chemical solutions such as solvents used in resist compositions and various organic solvents contain metal components such as trace metal fine particles, trace metals and trace metal ion impurities.

These metal components are originally contained in a chemical solution in some cases, but they are also incorporated due to contamination from a chemical solution transfer path such as a pipe or a joint in some cases.

According to the filtration material of the present embodiment, various metal components such as lithium, sodium, magnesium, potassium, chromium, manganese, iron, cobalt, nickel, copper, zinc, strontium, molybdenum, silver, cadmium, tin, antimony, barium and lead can be removed.

According to the filtration material of the present embodiment, even in the case where two or more kinds of the above metal components are present in a mixture, the metal components can be removed.

Among the above-described metal components, metal components having a high ionization tendency and zinc which is easily introduced due to contamination during the manufacturing process can be effectively removed.

Further, the filtration material of the present embodiment forms a predetermined chelate structure with a metal ion, but the group represented by the aforementioned general formula (a0-1) characteristic of the present embodiment efficiently forms a chelate structure, in particular, with an alkali metal such as lithium, sodium and potassium. Therefore, the filtration material of the present embodiment is capable of suitably removing these metals from the liquid to be filtered.

According to the filtration material of the present embodiment, it is possible to remove the above trace metals, including the metal ions, the metal fine particles and the like, regardless of their existing forms.

By passing a resist composition or an organic solvent through the filtration material of the present embodiment (that is, chelating silica having a group represented by general formula (a0-1)), the concentration of the metal components in the resist composition or the organic solvent can be reduced to less than 500 parts per trillion (ppt), less than 100 ppt, or even less than 10 ppt.

### <<Filtration Filter>>

The present embodiment is a filtration filter using the above-described filtration material. As the filtration filter of the present embodiment, a filter formed by filling a cylindrical container having a liquid inlet and a liquid outlet with the filtration material may be exemplified.

The shape of the filter and the amount of the filtration material used for filling can be suitably adjusted and may be suitably selected according to a resist composition to be filtered, an organic solvent, and the like.

The shape of the filtration filter of the present embodiment may be a flat shape, a roll shape, a cone shape, a pleated shape, a spiral shape, a layered type, or a combination of these. Among these, a flat shape or a roll shape is preferable.

Moreover, the filtration filter of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

### <<Filtration Method>>

The present embodiment is a filtration method characterized by passing a resist composition or an organic solvent through the filtration filter for a resist composition or for an organic solvent to remove impurities in the resist composition or the organic solvent.

The filtration method of the present embodiment can be performed using (1) a method (column method) of filling a column with the filtration material and passing a resist composition or an organic solvent through the column for purification and (2) a method (batch method) of placing the filtration material in a resist composition or an organic solvent and mixing and stirring the resultant for a predetermined time for removal. In the case of the batch method, it is necessary to separate the resist composition or the organic solvent from the filtration material after stirring for a predetermined time. The separation method is typically carried out through filtration using a filter or carried out using a centrifugation technique.

The resist composition used in the column method or the batch method is preferably a solution having a concentration within a range of about 1 to 50% by weight.

The flow rate of the resist composition or the organic solvent at the time of passing through the filtering material has almost no influence on the efficiency of metal separation, and may be usually in a range of 0.0001 to 1,000 kg/(m²·min). If the temperature at which a solution is passed through a filter or the like filled with the filtration material is too high, there is a concern that elution or deterioration of the filtering medium or degradation of a solvent may occur. On the other hand, if the temperature is too low, the viscosity of the resin in the solution becomes high, making it very difficult to pass the solution. Therefore, the appropriate range of the temperature is 0° C. to 50° C.

In the filtration method of the present embodiment, metal components can be suitably removed as impurities.

According to the filtration method of the present embodiment, various metal components such as lithium, sodium, magnesium, potassium, chromium, manganese, iron, cobalt, nickel, copper, zinc, strontium, molybdenum, silver, cadmium, tin, antimony, barium and lead can be removed.

According to the filtration method of the present embodiment, even in the case where two or more kinds of the above metal components are present in a mixture, the metal components can be removed.

Among the above-described metal components, metal components having a high ionization tendency and zinc which is easily introduced due to contamination during the manufacturing process can be effectively removed.

According to the filtration method of the present embodiment, it is possible to remove the above trace metals, including the metal ions, the metal fine particles and the like, regardless of their existing forms.

The filtration material according to the present embodiment into which the group represented by general formula (a0-1) has been introduced enables efficient and simultaneous removal of particulate impurities and trace metal impurities using exactly the same apparatus and operation as in the related art, by replacing, or using in combination with, a filter cartridge or the like for removing the particulate impurities installed in the related art in the supply line or point of use (POU) of various chemical liquids in the semiconductor production process. That is, since trace metal impurities are removed in a single filtration step, application of the present embodiment to real devices currently used in the production of semiconductor devices becomes very easy, and also from this point of view, the effects of the present embodiment on the semiconductor industry are enormous.

The metal impurities in the chemical liquid can be greatly reduced by installing the filter cartridge according to the present embodiment in the course of a path circulating the chemical tank in various chemical liquid supply lines in the semiconductor device manufacturing process. Further, by placing the filter according to the present embodiment at the point of use (POU) in the chemical liquid supply line, it is possible to efficiently remove metal impurities and particulate impurities in various chemical solutions. Furthermore, in this case, not only the metal impurities originally contained in the chemical solution can be removed, but also it becomes possible to cope with contamination from a chemical solution transfer path such as a pipe or a joint.

### <<Filtration Material 2>>

A second aspect of the present invention is a filtration material characterized by using a porous base material having a group represented by the following general formula (a0-1).

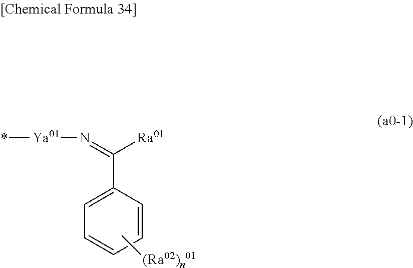

[In formula (a0-1), Ya⁰¹ represents a divalent linking group; Ra⁰¹ represents a hydrocarbon group which may have a substituent;

Ra⁰² represents a hydroxyl group or a hydrocarbon group having 1 to 6 carbon atoms which may have a substituent; n⁰¹ represents an integer of 0 to 5; and the symbol “*” represents a valence bond with respect to the porous base material.]

In general formula (a0-1), Ya⁰¹, Ra⁰¹, Ra⁰² and n⁰¹ are the same as defined above.

The filtration material according to the second aspect of the present invention uses a porous base material having a group represented by the above general formula (a0-1). Examples of the filtration material include a material obtained by modifying a known porous base material with a group represented by general formula (a0-1) (hereinafter, may be referred to as “modified porous base material” in some cases), and a material using a polymer obtained by polymerizing a structural unit having a group represented by general formula (a0-1) (hereinafter, may be referred to as “polymerizable porous base material” in some cases).

### [Modified Porous Base Material]

The modified porous base material in the second aspect of the present invention will be described.

Specific examples of the modified porous base material include a porous material as shown in the following (BM)-1.

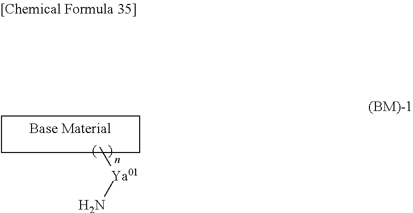

[In the formula, “Base Material” refers to a known porous base material, Ya⁰¹ represents a divalent linking group, and n represents a natural number.]

In formula (BM)-1, Ya⁰¹ represents a divalent linking group, and the description regarding the divalent linking group is the same as described above. n represents a natural number.

In formula (BM)-1, the “Base Material” refers to a known porous base material, and specific examples of preferred materials include a filter using a resin material.

Examples of such filters using a resin material include filters which use a thermoplastic resin material, such as polyethylene, polypropylene, polyolefin which includes the same polyolefin, such as a homopolymer of polyolefin, a copolymer of polyolefin, or a terpolymer of polyolefin, polyvinylidene fluoride (PVDF), a PTFE resin, PFA, and other fluoride resins, a perfluorinated thermoplastic resin, a homopolymer and a copolymer of polyvinyl chloride (PVC), plastic, for example, a cellulose derivative material such as regenerated cellulose or nitrocellulose, nylon, polyamide, polysulfone, modified polysulfone such as polyether sulfone, polyaryl sulfone, or polyphenyl sulfone, polyimide, polycarbonate, PET and polyester similar to PET, and a mixture of these.

Among these, polyethylene (PE), polypropylene (PP), polytetrafluoroethylene (PTFE), polyester, cellulose, polyamide, nylon and the like are preferable, and polytetrafluoroethylene (PTFE) is particularly preferable.

In formula (BM)-1, as the “Base Material”, an inorganic material such as stainless steel, nickel and carbon may be employed, or a composite material obtained by combining the above-described resin material and the inorganic material may be employed.

More specifically, for example, a non-woven fabric filter obtained by entangling resins or fibers of a metal or a mesh filter obtained by knitting resins or fibers of a metal can be used.

In the filtration material according to the second aspect of the present invention, the modified porous base material can be appropriately selected to have a desired shape by a known porous base material to be employed. When a filter using the above resin material is employed as a known porous base material, the shape thereof may be a flat shape, a roll shape, a cone shape, a pleated shape, a spiral shape, a layered type, or a combination of these. Among these, a flat shape or a roll shape is preferable.

Furthermore, the filter having a flat shape may be used, for example, as a cut disk having a diameter of 20 mm to 300 mm.

Moreover, the filtration filter of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

### [Polymerizable Porous Base Material]

The polymerizable porous base material in the present embodiment will be described. As the polymerizable porous base material, for example, a polymer compound having a structural unit represented by the following general formula (BM)-2 (hereinafter, may be referred to as “polymer compound (BM)” in some cases) can be used.

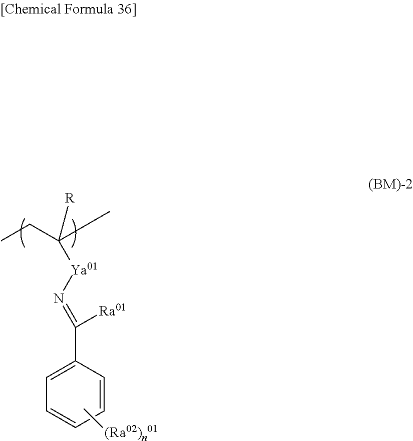

[In the general formula (BM)-2, R represents a hydrogen atom, an alkyl group having 1 to 5 carbon atoms or a halogenated alkyl group having 1 to 5 carbon atoms; Ya⁰¹ represents a divalent linking group; Ra⁰¹ represents a hydrocarbon group which may have a substituent; Ra⁰² represents a hydroxyl group or a hydrocarbon group having 1 to 6 carbon atoms which may have a substituent; and n⁰¹ represents an integer of 0 to 5.]

In the general formula (BM)-2, as the alkyl group having 1 to 5 carbon atoms for R, a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group. The halogenated alkyl group having 1 to 5 carbon atoms is a group in which some or all of the hydrogen atoms of the alkyl group having 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In the general formula (BM)-2, Ya⁰¹, Ra⁰¹, Ra⁰² and n⁰¹ are the same as defined above for Ya⁰¹, Ra⁰¹, Ra⁰² and n⁰¹ in the above general formula (a0-1).

In particular, as the divalent linking group for Ya⁰¹ in the general formula (BM)-2, among the divalent linking groups for Ya⁰¹ in the above general formula (a0-1), a divalent linking group containing a hetero atom is preferable. More specific examples thereof include —C(═O)—NH—, —NH—, —NH—C(═NH)— (here, H may be substituted with a substituent such as an alkyl group or an acyl group), a group represented by general formulas —Y²¹—O—Y²²—, —Y²¹—O—, —Y²¹—C(═O)—O—, —C(═O)—O—Y²¹—, —[Y²¹—C(═O)—O]_{m′}—Y²²—, —Y²¹—O—C(═O)—Y²²—, —Y²¹—C(═O)—NH—Y²²—, —Y²¹—NH—, —Y²¹—C(═O)—NH—, —C(═O)—NH—Y²¹ or —[Y²¹—C(═O)—NH—]_{m′}—Y²²— [in the formulas, Y²¹ and Y²² each independently represents a divalent hydrocarbon group which may have a substituent; O represents an oxygen atom; and m′ represents an integer of 0 to 3].

As the divalent linking group for Ya⁰¹ in the general formula (BM)-2, a group represented by the general formula —Y²¹—C(═O)—NH—Y²²—, —Y²¹—NH—, —Y²¹—C(═O)—NH—, —C(═O)—NH—Y²¹ or —[Y²¹—C(═O)—NH—]_{m′}—Y²²— is preferable.

In a case where the divalent linking group containing a hetero atom represents —C(═O)—NH—, —NH—, or —NH—C(═NH)—, H may be substituted with a substituent such as an alkyl group or an acyl group. The substituent (an alkyl group, an acyl group or the like) preferably has 1 to 10 carbon atoms, more preferably 1 to 8 carbon atoms, and most preferably 1 to 5 carbon atoms.

In formulas —Y²¹—O—Y²²—, —Y²¹—O—, —Y²¹—C(═O)—O—, —C(═O)—O—Y²¹, —[Y²¹—C(═O)—O]_{m′}—Y²²— and —Y²¹—O—C(═O)—Y²²— and general formulas —Y²¹—C(═O)—NH—Y²²—, —Y²¹—NH—, —Y²¹—C(═O)—NH—, —C(═O)—NH—Y²¹ or —[Y²¹—C(═O)—NH—]_{m′}—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

Y²¹ is preferably a linear aliphatic hydrocarbon group, more preferably a linear alkylene group, still more preferably a linear alkylene group of 1 to 5 carbon atoms, and most preferably a methylene group or ethylene group.

Y²² is preferably a linear or branched aliphatic hydrocarbon group, and is more preferably a methylene group, ethylene group or alkylmethylene group. The alkyl group within the alkylmethylene group is preferably a linear alkyl group of 1 to 5 carbon atoms, more preferably a linear alkyl group of 1 to 3 carbon atoms, and most preferably a methyl group.

In the group represented by formula —[Y²¹—C(═O)—O]_{m′}—Y²²— or —[Y²¹—C(═O)—NH—]_{m′}—Y²²—, m′ represents an integer of 0 to 3, and is preferably an integer of 0 to 2, more preferably 0 or 1, and most preferably 1. In other words, it is particularly desirable that the group represented by the formula —[Y²¹—C(═O)—O]_{m′}—Y²²— be a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

Specific examples of the structural units represented by the general formula (BM)-2 are shown below.

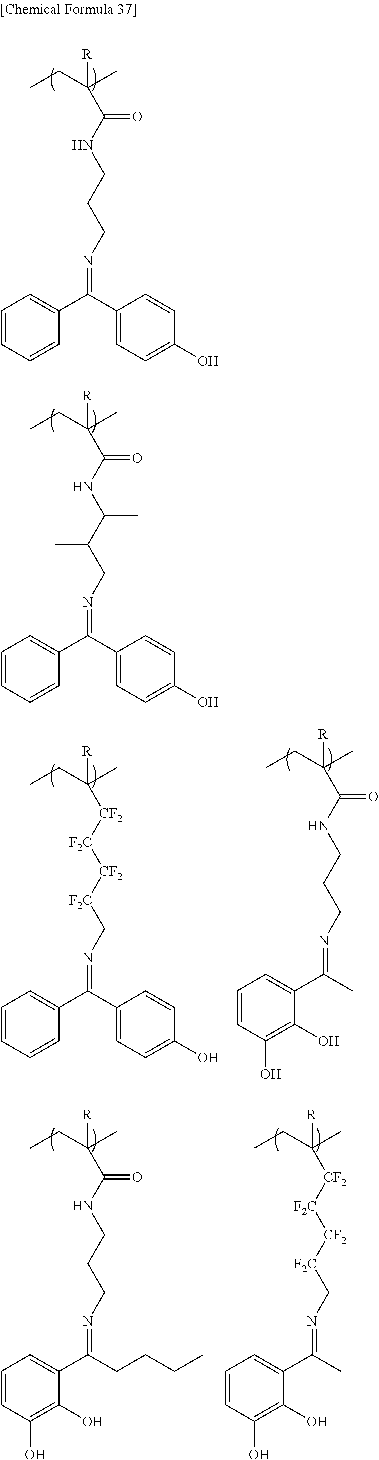

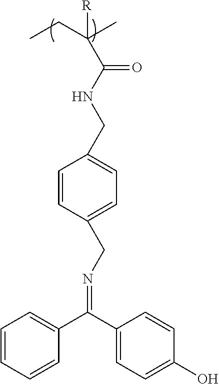

The proportion of the structural unit represented by the general formula (BM)-2 in the polymer compound (BM) is preferably in a range of 1% to 100% by mole, more preferably in a range of 20% to 100% by mole, and particularly preferably in a range of 30% to 100% by mole with respect to all structural units constituting the polymer compound (BM).

The structural unit represented by the general formula (BM)-2 may be used alone or in combination of two or more kinds thereof.

Moreover, the polymer compound (BM) may contain a structural unit other than the structural unit represented by the general formula (BM)-2, with the proviso that the effects of the present invention are not impaired.

Examples of the other structural units include a structural unit derived from an acrylate such as acrylic acid or an acrylamide monomer; a structural unit derived from 2-acrylamide-2-methyl-1-propanesulfonic acid; a structural unit derived from sulfopropyl acrylate or N,N-dimethyl acrylamide; and a structural unit derived from a methacrylamide monomer such as methacrylate or methacrylic acid.

The polymer compound (BM) can be obtained by polymerization, for example, known radical polymerization or the like, using a radical polymerization initiator such as azobisisobutyronitrile (AIBN) or dimethyl azobis(isobutyrate).

Further, a crosslinking agent may be used at the time of polymerization of the polymer compound (BM). As the crosslinking agent, compounds including an ethylenically unsaturated group can be used and these compounds can be used alone or in combination thereof. Preferred examples of the compounds including an ethylenically unsaturated group include polyacrylates of polyols such as ethylene glycol diacrylate, trimethylol propane triacrylate, ditrimethylol propane tetraacrylate, pentaerythritol triacrylate, pentaerythritol tetraacrylate, dipentaerythritol pentaacrylate, and dipentaerythritol hexaacrylate; epoxyacrylates such as diacrylate of bisphenol A diglycidyl ether and diacrylate of hexanediol diglycidyl ether; and urethane acrylate obtained by a reaction of hydroxyl group-containing acrylate such as polyisocyanate or hydroxyethyl acrylate.

In the filtration material according to the second aspect of the present invention, the shape of the polymerizable porous base material can be appropriately selected to be a desired shape. For example, the shape thereof may be a flat shape, a roll shape, a cone shape, a pleated shape, a spiral shape, a layered type, or a combination of these. Among these, a flat shape or a roll shape is preferable.

Furthermore, the filter having a flat shape may be used, for example, as a cut disk having a diameter of 20 mm to 300 mm.

Moreover, the filtration filter of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

### <<Production Method of Filtration Material>>

The present embodiment provides a method for producing a filtration material having a step of introducing a group represented by the following general formula (a0-1) to a porous base material having a terminal amino group.

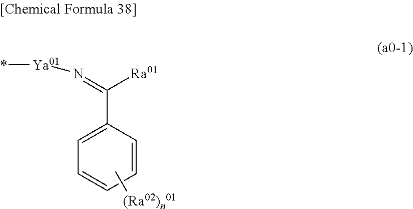

[In formula (a0-1), Ya⁰¹ represents a divalent linking group; Ra⁰¹ represents a hydrocarbon group which may have a substituent;

Ra⁰² represents a hydroxyl group or a hydrocarbon group having 1 to 6 carbon atoms which may have a substituent; n⁰¹ represents an integer of 0 to 5; and the symbol “*” represents a valence bond with respect to a porous base material having a terminal amino group.]

In general formula (a0-1), Ya⁰¹, Ra⁰¹, Ra⁰² and n⁰¹ are the same as defined above.

The method for producing a filtration material according to the present embodiment will be described in the case where the filtration material of the present embodiment is the aforementioned modified porous base material and the case where it is the aforementioned polymerizable porous base material.

### [Production Method of Modified Porous Base Material]

In the present embodiment, when the filtration material is the modified porous base material, for example, it is preferable to include a first step of modifying a known porous base material with an amino group to prepare a porous base material having a terminal amino group, and a second step of introducing a group represented by general formula (a0-1) into the porous base material having a terminal amino group obtained in the first step.

Reaction formulas for explaining the first step and the second step are shown below.

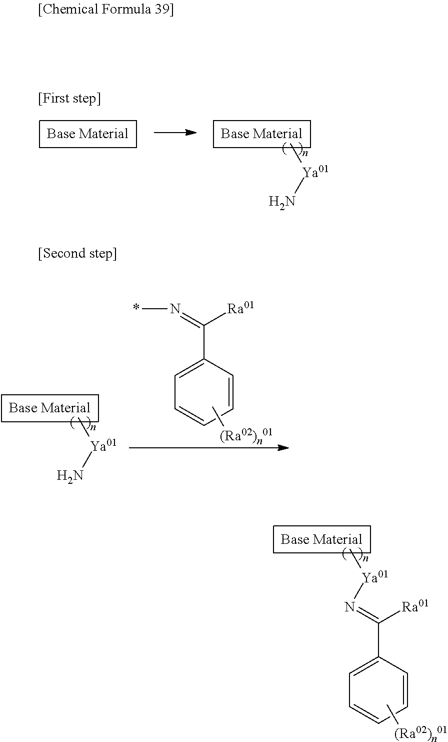

In the above formulas, Ya⁰¹, Ra⁰¹, Ra⁰² and n⁰¹ are the same as defined above.

For the modification with an amino group in the above [first step], a compound having an amino group at the side chain terminal or a polymer compound having an amino group at the side chain terminal may be modified with a crosslinking agent or the like.

Alternatively, a commercially available porous base material whose surface is modified with an amino group may be purchased as the first step.

In the above [second step], the group represented by general formula (a0-1) is introduced into the porous base material having a terminal amino group prepared in the [first step].

In an example using polytetrafluoroethylene (PTFE) as a known porous base material, in the [first step], the surface of a PTFE film is modified with an amino group and the amino group-modified PTFE is immersed in a solution in which the compound having a group represented by general formula (a0-1) is dissolved, thereby introducing the group represented by general formula (a0-1) into the PTFE film.

### [Production Method of Polymerizable Porous Base Material]

In the present embodiment, when the filtration material is the polymerizable porous base material, it can be produced by polymerizing the polymer compound (BM), and modifying a known porous base material with the polymer compound (BM) with a crosslinking agent or the like, or simply coating a known porous base material with the polymer compound (BM).

The filtration material produced by the method for producing a filtration material according to the present embodiment can be suitably used for filtering a resist composition or an organic solvent.

The description on the resist composition or the organic solvent is the same as described above.

The filtration material produced by the method for producing a filtration material according to the present embodiment is preferably used as a filtration filter, and the shape of the filtration filter can be appropriately selected to be a desired shape. For example, the shape thereof may be a flat shape, a roll shape, a cone shape, a pleated shape, a spiral shape, a layered type, or a combination of these. Among these, a flat shape or a roll shape is preferable.

Furthermore, the filter having a flat shape may be used, for example, as a cut disk having a diameter of 20 mm to 300 mm.

Moreover, the filtration filter of the present embodiment may be a cartridge type. As the cartridge type filter, for example, a cartridge device which is formed as one or more layers, and has pleats or is wound up spirally is preferable. Further, a cartridge device having a flat shape and sheet shape is more preferable.

### <<Filtration Method 2>>

The present embodiment provides a filtration method of passing a resist composition or an organic solvent through a filtration material produced by the method for producing a filtration material to remove impurities in the resist composition or the organic solvent.

For example, filtration can be carried out by installing a filtration filter produced by the method for producing a filtration material according to the present embodiment in the course of a path circulating the chemical tank in various chemical liquid supply lines in the semiconductor device manufacturing process and causing a resist composition or an organic solvent to pass through the filtration filter. Further, by placing the filter at the point of use (POU) in the chemical liquid supply line, it is possible to efficiently remove metal impurities and particulate impurities in various chemical solutions.

The flow rate of the resist composition or the organic solvent at the time of passing through the filtration filter has almost no influence on the efficiency of metal separation, and may be usually in a range of 0.0001 to 1,000 kg/(m²·min). If the temperature at which a solution is passed through a filter or the like filled with the filtration material is too high, there is a concern that elution or deterioration of the filtering medium or degradation of a solvent may occur. On the other hand, if the temperature is too low, the viscosity of the resin in the solution becomes high, making it very difficult to pass the solution. Therefore, the appropriate range of the temperature is 0° C. to 50° C.

The filtration filter according to the present embodiment into which the group represented by general formula (a0-1) has been introduced enables efficient and simultaneous removal of particulate impurities and trace metal impurities using exactly the same apparatus and operation as in the related art, by replacing, or using in combination with, a filter cartridge or the like for removing particulate impurities installed in the related art in the supply line or point of use (POU) of various chemical liquids in the semiconductor production process.

That is, since trace metal impurities are removed in a single filtration step, application of the present embodiment to real devices currently used in the production of semiconductor devices becomes very easy.

### <<Copolymer>>

A sixth aspect of the present invention is a copolymer of a bifunctional or higher functional alkoxysilane which is a copolymer having a partial structure represented by the above general formulas (p-1) and (p-3), and it is the same as the “copolymer 1” in the description of the first aspect.

A seventh aspect of the present invention is a copolymer of a bifunctional or higher functional alkoxysilane which is a copolymer having a partial structure represented by the above general formulas (p-1) and (p-5), and it is the same as the “copolymer 2” in the description of the first aspect.

### <<Method 1 for Producing Copolymer>>

An eighth aspect of the present invention is a method for producing the copolymer of the present invention, the method characterized by including: a step A of reacting a compound represented by the following general formula (1) with a compound represented by the following general formula (2) to obtain a copolymer (A) having a partial structure represented by the following general formulas (p-1) and (p-2); a step B of modifying the copolymer (A) obtained in the step A to obtain a copolymer (B) having a partial structure represented by the following general formula (p-B-1); and a step C of modifying the copolymer (B) obtained in the step B to obtain a copolymer (C) having a partial structure represented by the following general formulas (p-3) and (p-1).

The method for producing a copolymer according to the eighth aspect of the present invention is the same as the “Production method of copolymer 1” in the description of the first aspect.

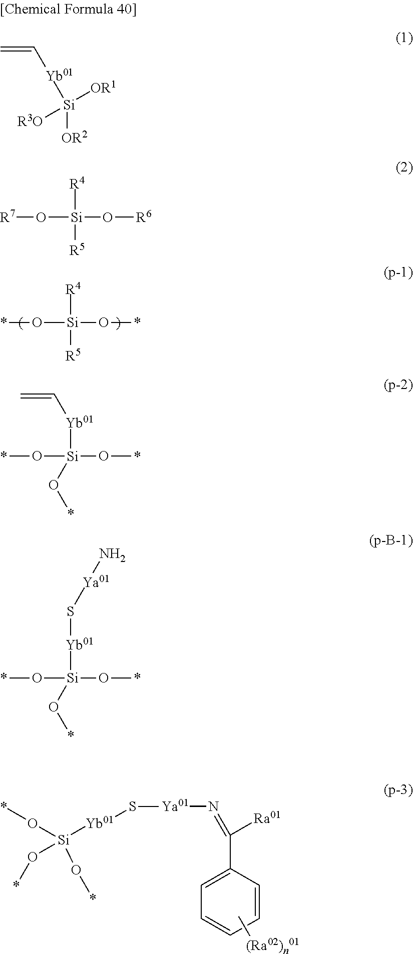

[In the formulas, R¹ to R³ and R⁶ to R⁷ each independently represent an alkyl group having 1 to 5 carbon atoms, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

### <<Method 2 for Producing Copolymer>>

A ninth aspect of the present invention is a method for producing the copolymer according to the second aspect of the present invention, the method characterized by including: a step X of obtaining a copolymer (X) having a partial structure represented by the following general formulas (p-1) and (p-4) by reacting a compound represented by the following general formula (3) with a compound represented by the following general formula (2); a step Y of obtaining a copolymer (Y) having a partial structure represented by the following general formula (p-Y-1) by modifying the copolymer (X) obtained in the step X; and a step Z of obtaining a copolymer (Z) having a partial structure represented by the following general formulas (p-5) and (p-1) by modifying the copolymer (Y) obtained in the step Y.

The method for producing a copolymer according to the ninth aspect of the present invention is the same as the “Production method of copolymer 2” in the description of the first aspect.

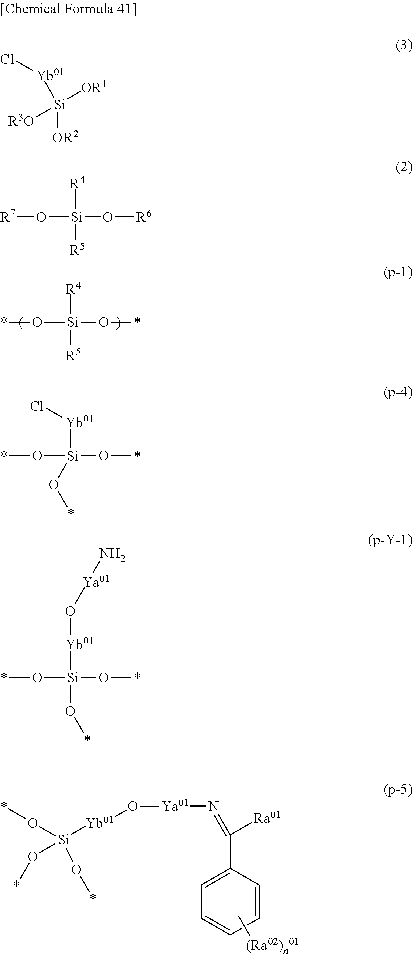

[In the formulas, R¹ to R³ and R⁶ to R⁷ each independently represent an alkyl group having 1 to 5 carbon atoms, R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.]

### <<Copolymer>>

A tenth aspect of the present invention is a copolymer of an alkoxysilane having two or more functional groups, the copolymer having a partial structure represented by the following general formulas (p-1) and (p-4).

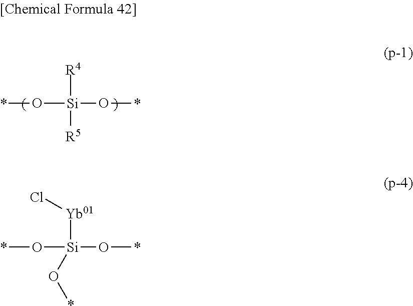

[In the formulas, R⁴ and R⁵ each independently represent an alkyl group having 1 to 5 carbon atoms, and one of R⁴ and R⁵ may be a hydroxyl group, and may be bonded to another silicon atom in the alkoxysilane copolymer to form a crosslinked structure; Yb⁰² represents a divalent linking group; and the symbol “*” represents a valence bond.]

In the above formula, R⁴, R⁵ and Ya⁰² are the same as defined above.

By using the copolymer of the present embodiment, it is possible to remove impurities, particularly metal components with high removal efficiency. Chemical solutions such as solvents used in resist compositions and various organic solvents contain metal components such as trace metal fine particles, trace metals and trace metal ion impurities.

These metal components are originally contained in a chemical solution in some cases, but they are also incorporated due to contamination from a chemical solution transfer path such as a pipe or a joint in some cases.

By using the copolymer of the present embodiment, various metal components such as lithium, sodium, magnesium, potassium, chromium, manganese, iron, cobalt, nickel, copper, zinc, strontium, molybdenum, silver, cadmium, tin, antimony, barium and lead can be removed.

By using the copolymer of the present embodiment, even in the case where two or more kinds of the above metal components are present in a mixture, the metal components can be removed.

Among the above-described metal components, metal components having a high ionization tendency and zinc which is easily introduced due to contamination during the manufacturing process can be effectively removed.

Further, the copolymer of the present embodiment forms a predetermined chelate structure with a metal ion, but the partial structure represented by the general formulas (p-1) and (p-5) characteristic of the present invention efficiently forms a chelate structure, in particular, with an alkali metal such as lithium, sodium and potassium. Therefore, the copolymer of the present invention is capable of suitably removing these metals from the liquid to be filtered.

By using the copolymer of the present embodiment, it is possible to remove the above trace metals, including the metal ions, the metal fine particles and the like, regardless of their existing forms.

By passing a resist composition or an organic solvent through the copolymer of the present embodiment (that is, a copolymer having a partial structure represented by the general formulas (p-1) and (p-5)), the concentration of the metal components in the resist composition or the organic solvent can be reduced to less than 500 parts per trillion (ppt), less than 100 ppt, or even less than 10 ppt.

### EXAMPLES

The present invention will be described more specifically with reference to the following examples, although the scope of the present invention is by no way limited by these examples.

### Example 1: Synthesis of Metal Component Removing Material Using Silica Gel

Synthesis was conducted with reference to literature (A. Goswami et al., Anal. Chimi. Acta 2002 454, 229-240).

Anhydrous ethanol (200 g) obtained by dissolving amino group-modified silica gel (particle size: 50 μm, 100 g) and 40 g of 2,4-dihydroxyacetophenone (hereinafter, may be described as “resacetophenone” in some cases) was added to a light shielding glass bottle for chemical liquid products and stirred for 18 hours.

Thereafter, silica was collected by filtration, washed with anhydrous ethanol, and further washed with anhydrous diethyl ether. The obtained silica powder was vacuum-dried at 80° C. for 12 hours to obtain yellow silica. The reason why the silica turns yellow is due to the color development of the phenylimine group obtained by dehydration condensation of the ketone moiety of resacetophenone and the amino group of silica.

Furthermore, after the chelating moiety modification, a rise in the peaks attributable to the benzene ring at 1493 cm⁻¹ and 1612 cm⁻¹ was markedly confirmed by FT-IR. According to the above process, the successful synthesis of a metal component removing silica gel material having a chelating ability (hereinafter, sometimes referred to as “chelating silica gel”) was conducted in a simple manner. The synthesis scheme is shown below.

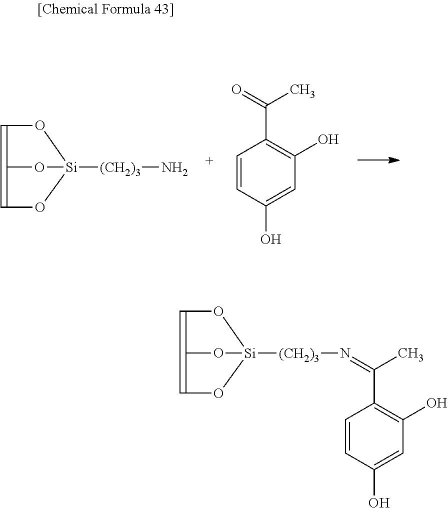

### Example 2: Evaluation of Metal Ion Removal by Metal Component Removing Material

<Removal of Metal Ion from Metal Aqueous Solution>

Iron chloride, copper sulfate and nickel chloride were each dissolved in pure water so as to achieve a concentration of 3,000 ppm to prepare the respective aqueous solutions. 5 mL of each aqueous solution was added to a vial bottle, and after 2 g of the chelating silica obtained in Example 1 was charged thereto, the resulting mixture was stirred for 5 minutes and subjected to filtration.

Table 1 shows the results of visual observation of the color of the metal-adsorbed chelating silica and the filtrate before the filtration of each metal aqueous solution.

As shown in Table 1, in the aqueous solution colored by each metal ion, the chelating silica gel and the metal ion formed a chelate to adsorb the metal ion, and a change in the color of the silica was observed. Especially in the case of an iron ion, the silica instantly turned red. This indicates that the ligand of silica and the iron ion formed a chelate. Since the obtained filtrate was transparent, it was confirmed that complete adsorption of metal ions was successfully performed.

<Removal of Metal Ion from Metal Solution>

A similar experiment was also carried out in the same manner using a cyclohexanone/acetonitrile solution in which 3,000 ppm of iron chloride was dissolved. The silica was colored red and the recovered filtrate became colorless. From this result, it was found that this chelating silica can also be applied to organic solvents.

TABLE 1

| | | | Metal- | |
|---|---|---|---|---|
| | | | adsorbed | |
| | | Before | chelating | |
| | Solvent | filtration | silica gel | Filtrate |
| Iron chloride | Pure water | Yellowish | Red | Colorless |
| | | brown | | |
| Iron chloride | Cyclohexanone/ | Yellowish | Red | Colorless |
| | acetonitrile = 1/1 | brown | | |
| Copper sulfate | Pure water | Blue | Blue | Colorless |
| Nickel chloride | Pure water | Yellow | Yellow | Colorless |

### Example 3: Evaluation of Metal Nanoparticle Removal by Metal Component Removing Material

Metal nanoparticles are assumed as one of the causes of metal residue. Accordingly, the removal of metal nanoparticles by passing through a chelating silica column was evaluated.

### <Preparation of Chelating Silica Column>

A 5 mL PTFE syringe equipped with a 0.45 μm filter was packed with the chelating silica gel obtained in Example 1 to prepare a column.

### <Removal of Metal Nanoparticles>

A nanoparticle dispersion liquid in which tin oxide nanoparticles (20 nm) were dispersed in cyclohexanone so as to achieve a concentration of 300 ppm was prepared to obtain a white turbid dispersion.

This dispersion (3 ml) was passed through the aforementioned column, and the resulting liquid was collected. When the white turbid dispersion was passed through the column, the resulting liquid became colorless. From this result, successful removal of nanoparticles through the adsorption of tin oxide nanoparticles on the chelating silica gel by physical adsorption was confirmed.

### Example 4: Quantitative Evaluation of Metal Component Removal

### Test Example 1: Test for Metal Contamination Caused by Filters

A test was conducted in order to evaluate contamination caused by a trace amount of metals eluted from the equipment to be used or the like.

In order to compare the influence of contamination caused by 0.45 μm filters, cyclohexanone before distillation and cyclohexanone after distillation were each passed through a 0.45 μm filter (hereinafter, sometimes described as “empty filter”) to carry out the analysis of metal components by ICP-MS. The results are shown in Tables 2 to 5. In Tables 2 to 5, numerical values are expressed in the unit of ppt.

As a result, for example, in the case of Fe in Table 3, even when cyclohexanone after distillation was used, although only 7 ppt of Fe was present before the filtration using the filter, 22 ppt of Fe was detected after the filtration using the filter.

From this result, metal contamination due to the filter was confirmed.

### Test Example 2: Quantitative Evaluation of Metal Component Removal Using Chelating Silica Gel Column

1 g of the chelating silica gel of Example 1 was added to 50 mL of cyclohexanone (before distillation), and the resulting mixture was stirred for 30 minutes to prepare a slurry. Next, 5 mL of chelating silica was filled in a 10 mL syringe equipped with a 0.45 μm PTFE filter.

Then, the resultant was washed with 6 mL of cyclohexanone (before distillation), and after washing, 10 mL of cyclohexanone (before distillation) was passed therethrough, and the initial portion of the filtrate was discarded. Thereafter, the remainder was passed therethrough, and 20 mL of filtered cyclohexanone (before distillation) was recovered.

Metal components in the recovered liquid were analyzed by ICP-MS. The results are shown in Tables 2 to 5.

The levels of Fe and Cr were almost the same as those in the liquid that passed through an empty filter. As also shown in Test Example 1, in the case of Fe, the amount of metal components in cyclohexanone after distillation which passed through an empty filter also increases. From this result, it was suggested that the amount of metal components increased due to the contamination caused by the filter, although the intrinsic Fe components in cyclohexanone were successfully collected by using the chelating silica.

Therefore, it was found that the amount of metal components in cyclohexanone filtered by the filter packed with the chelating silica of Example 1 was equal to or less than that in cyclohexanone after distillation.

In the case of Ni, the amount of metal components was equivalent to that in cyclohexanone after distillation which was not passed through an empty filter.

From the above result, the metal trapping effect of the chelating silica was equal to or higher than that after distillation. Furthermore, it was found from all the samples that it was remarkably effective in removing metal components such as Li, Na, K and Zn.

TABLE 2

| | Li | Na | Mg | K | Cr |
|---|---|---|---|---|---|
| Before distillation | 74 | 5831 | 67 | 193 | 84 |
| After distillation | 680 | 276 | 117 | 151 | 11 |
| Before distillation | 84 | 4947 | 81 | 152 | 99 |
| (Filtration by empty filter) | | | | | |
| After distillation | 126 | 264 | 108 | 95 | 26 |
| (Filtration by empty filter) | | | | | |
| Before distillation | 16 | 205 | 102 | 26 | 24 |
| Filtration by chelating silica gel | | | | | |

TABLE 3

| | Mn | Fe | Co | Ni | Cu |
|---|---|---|---|---|---|
| Before distillation | 4 | 83 | 2 | 9 | 30 |
| After distillation | 5 | 7 | 2 | 9 | 16 |
| Before distillation | 8 | 81 | 3 | 8 | 37 |
| (Filtration by empty filter) | | | | | |
| After distillation | 8 | 22 | 3 | 27 | 32 |
| (Filtration by empty filter) | | | | | |
| Before distillation | 7 | 21 | 2 | 11 | 20 |
| Filtration by chelating silica gel | | | | | |

TABLE 4

| | Zn | Sr | Mo | Ag | Cd |
|---|---|---|---|---|---|
| Before distillation | 163 | 3 | 27 | 1 | 2 |
| After distillation | 334 | 6 | 0 | 1 | 3 |
| Before distillation | 188 | 1 | 23 | 1 | 6 |
| (Filtration by empty filter) | | | | | |
| After distillation | 337 | 2 | 1 | 2 | 6 |
| (Filtration by empty filter) | | | | | |
| Before distillation | 97 | 1 | 1 | 0 | 6 |
| Filtration by chelating silica gel | | | | | |

TABLE 5

| | Sn | Sb | Ba | Pb |
|---|---|---|---|---|
| Before distillation | 3 | 1 | 3 | 1 |
| After distillation | 4 | 1 | 7 | 1 |
| Before distillation | 22 | 1 | 5 | 4 |
| (Filtration by empty filter) | | | | |
| After distillation | 23 | 1 | 8 | 4 |
| (Filtration by empty filter) | | | | |
| Before distillation | 21 | 1 | 6 | 2 |
| Filtration by chelating silica gel | | | | |

### Example 5: Synthesis of Chelating Silica Gel with Large Particle Size

Chelating silica having a large particle size was synthesized in the same manner as in Example 1 except that silica having a particle size of 5 mm was used. It was confirmed that a chelating silica gel having a particle size of 5 mm was obtained.

### Examples 6 to 8: Synthesis and Evaluation of Chelating Silica Gel Compound

Chelating silica was synthesized using a compound having a skeleton similar to that of resacetophenone.

### Example 6

A chelating silica gel was synthesized in the same manner as in Example 1 except that the following compound 1 was used as a chelate precursor material and the amount added with respect to 3 g of an amino silica gel was changed to 6.0 g.

### Example 7

A chelating silica gel was synthesized in the same manner as in Example 1 except that the following compound 2 was used as a chelate precursor material and the amount added with respect to 3 g of an amino silica gel was changed to 7.0 g.

### Example 8

A chelating silica gel was synthesized in the same manner as in Example 1 except that the following compound 3 was used as a chelate precursor material and the amount added with respect to 3 g of an amino silica gel was changed to 4.0 g.

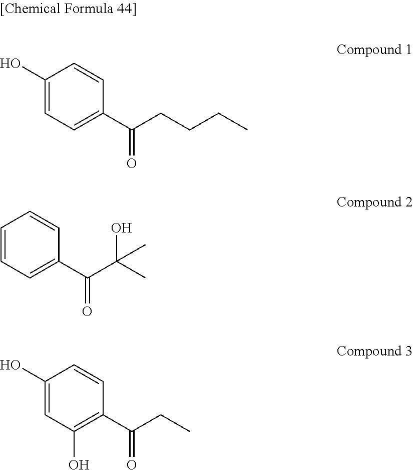

As a result, even in the case of using the above compounds 1 to 3, since the bright white amino silica gel was colored, it was possible to synthesize three types of chelating silica gel materials (Examples 6 to 8).

### Example 9: Metal Trapping Test of Chelating Silica Gel

A metal trapping test was conducted using the chelating silica gel materials of Examples 6 to 8.

4 ml of an FeCl₃ ethanol solution was added dropwise to 1 g of each of the chelating silica gels of Examples 6 to 8, and after stirring the resulting mixture for 5 minutes, silica was removed by filtration. As in the case of the chelating silica material of Example 1, in all the samples using each of the chelating silica gels of Examples 6 to 8, the removed silica turned red and the filtrate became colorless. From this result, it was confirmed that it was possible to collect iron using the chelating silica gels of Examples 6 to 8.

As shown in the above results, it was possible to remove metal ions or metal nanoparticles in the organic solvent with high efficiency by using the chelating silica of the present embodiment as a filtration material.

Since the organic solvent occupies 90% by weight or more of the resist composition, from the above results showing that it was possible to remove the metal components in the organic solvent with high efficiency, it is thought that the metal components in the resist composition can also be removed with high efficiency by using the filtration material of the present embodiment.

### Example 10: Synthesis of Aminosilica Xerogel Material for Metal Component Removal Using Silica Xerogel

### <Synthesis of Silica Xerogel>

Synthesis was conducted with reference to literature (G. Hayase, et. al., Angew. Chem. Int. Ed., 2013, 52, 10788-10791, G Hayase, et. al., Angew. Chem. Int. Ed., 2013, 52, 1986-1989. and G Hayase, et. al., J. Mater. Chem., 2011, 21, 17077-17079).

Urea (10 g) and n-hexadecyltrimethylammonium chloride (CTAC) (0.8 g) were dissolved in a 0.05 mol/L aqueous acetic acid solution (15 ml), and a bifunctional silane coupling agent: dimethyldimethoxysilane (DMDMS) (5 ml) and a trifunctional silane coupling agent: vinyltrimethoxysilane (VTMS) (5 ml) were added thereto, and the resulting mixture was stirred for 1 hour to conduct a sol reaction. After completion of the reaction, the resulting solution was allowed to stand in an oven at 80° C. and a gel reaction was carried out for 24 hours.

The obtained gel was washed three times with water, and then water was replaced with a water-isopropanol (IPA) (1:1) solution to wash the gel. The washed gel was immersed in IPA twice for 8 hours. Thereafter, it was washed three times with n-hexane and dried at 40° C. for 24 hours to obtain a xerogel.

The obtained gel had a marshmallow-like appearance and flexibility, and when it was immersed in a solvent, it was confirmed to instantaneously absorb the solvent. From the above result, it was confirmed that a silica xerogel was successfully synthesized. The synthesis scheme of silica xerogel is shown below. In the following, a wavy line represents a valence bond.

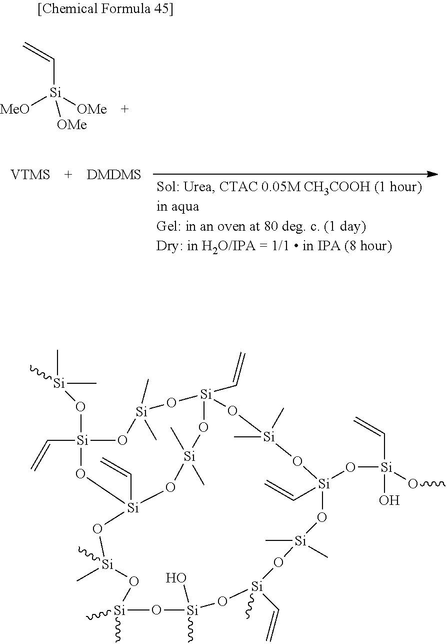

### <Synthesis of Aminosilica Xerogel>

A thiol-ene reaction was employed for the amino group modification of silica xerogel. 10 ml of a 10 wt % isopropanol (IPA) solution of 2-aminoethanethiol was prepared, and 0.2 g of a radical initiator (V-601) was dissolved therein. 2 g of the silica xerogel was immersed in the solution for 6 hours (at 65° C.) to convert the vinyl group at the terminal of the silica xerogel into a sulfide group. After the reaction, the silica xerogel was thoroughly washed with IPA and then washed with diethyl ether, followed by drying.

Since S2p was detected after the reaction by X-ray photoelectron spectroscopy (XPS), it was confirmed that the silica xerogel was successfully modified with aminoethane sulfide to obtain an aminosilica xerogel. The modification scheme of the silica xerogel with aminoethane sulfide is shown below. In the following, a wavy line represents a valence bond.

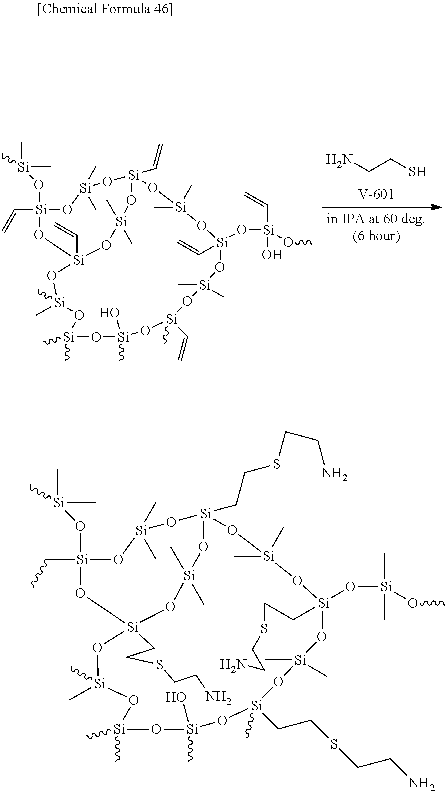

### <Synthesis of Chelating Silica Xerogel>

A chelating moiety in the aminosilica xerogel was selected and modified by immersing 2 g of an aminosilica xerogel in 20 ml of a 10 wt % ethanol solution of resacetophenone for 1 day. After immersion, the gel was taken out, thoroughly washed with ethanol and then washed with diethyl ether, and dried at 60° C. for 24 hours. As in the case of bead silica gels synthesized in the related art, in the resulting xerogel, a carbonyl group was dehydrated and condensed with the amino moiety to form a phenylacetimino group, and the xerogel was colored yellow. Also in the case of using 2,4-dihydroxy mevaloacetophenone, a chelating silica xerogel colored in the same light brown color as the bead silica gels was obtained by the same method. From the above result, it was confirmed that a chelating silica xerogel was successfully synthesized which had never existed. The synthesis scheme of the chelating silica xerogel is shown below. In the following, a wavy line represents a valence bond.

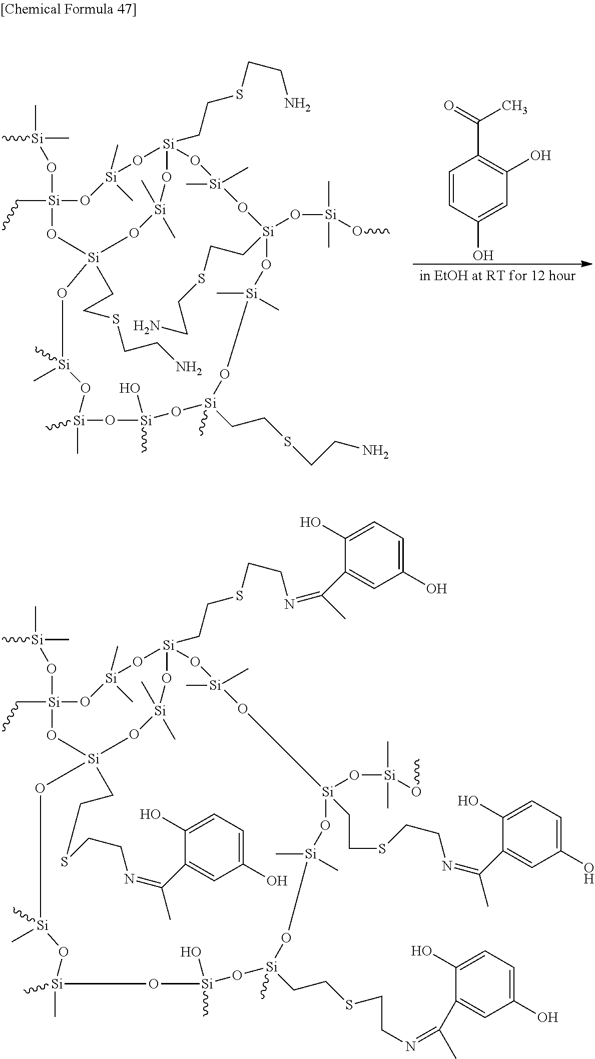

### Example 11: Evaluation of Metal Ion Removal by Chelating Silica Xerogel Material for Metal Component Removal

The metal component trapping by the chelating silica xerogel was evaluated qualitatively. A 50 ppm FeCl₃ cyclohexanone acetonitrile (1:1) solution was prepared, and the chelating silica xerogel was charged thereto and immersed for about 2 minutes, and then the xerogel turned from yellow to blood red due to the chelate formation between iron ions and the chelating moiety. In order to remove the xerogel, filtration was carried out using a 0.20 μm PTFE filter. The resulting filtrate turned from yellow to colorless. From this result, it was confirmed that metal components were also successfully trapped in the case of using the chelating silica xerogel.

### Example 12: Synthesis of Aminosilica Xerogel Material for Metal Component Removal Using Chloride Silica Xerogel

### <Synthesis of Chloride Silica Xerogel>

The synthesis of a novel silica xerogel was carried out by the method described above so that the polymerization ratio was 1:1 using a bifunctional silane coupling agent (dimethyldimethoxysilane) and a trifunctional silane coupling agent (chloride propyltrimethoxysilane). The yield of the obtained gel seemed to decrease slightly in the case of using chloride as compared with the case of using a vinyl methyl silica xerogel. It is suggested that this is due to the influence of reaction inhibition by the terminal functional group. However, in each of the obtained silica xerogels, since the peak of Cl2p was confirmed in the chloride silica xerogel by the XPS measurement, it was confirmed that the novel chloride silica xerogel was successfully synthesized. In the following, a wavy line represents a valence bond.

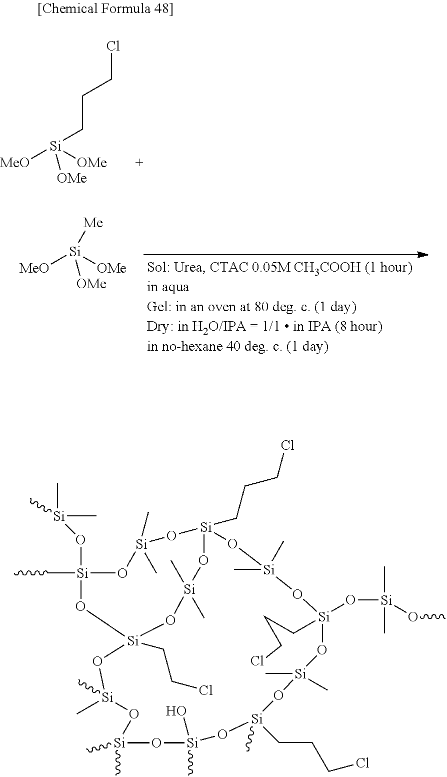

### <Synthesis of Chelating Silica Xerogel Using Chloride Silica Xerogel>

Amino group modification using a chloride silica xerogel was examined by the Williamson ether synthesis reaction using an amine alcohol. 1 g of chloride silica xerogel was added into a container, and 5 g of monoethanolamine with respect to the silica xerogel and 5 g of triethylamine as a nucleophilic reagent were charged respectively, and the resulting mixture was heated at 65° C. for 6 hours. Ultrapure water was added after heating to carry out washing and hydrolysis simultaneously, and then the resultant was thoroughly washed with ethanol. After washing, the resultant was passed through diethyl ether and dried at 60° C. The obtained silica gel was immersed in 2 wt. % ethanol solutions of resacetophenone and 2,4-dihydroxy mevaloacetophenone, respectively, and since the xerogel was colored after washing, etherification from chloride and successful amino group modification were indicated. At the same time, it was shown that this amine group-modified silica xerogel was chelate-modified. From the above result, it was confirmed that a novel synthetic route for chelating silica xerogels was successfully developed.

The synthetic scheme of amide silica using a chloride silica xerogel is shown below. In the following, a wavy line represents a valence bond.

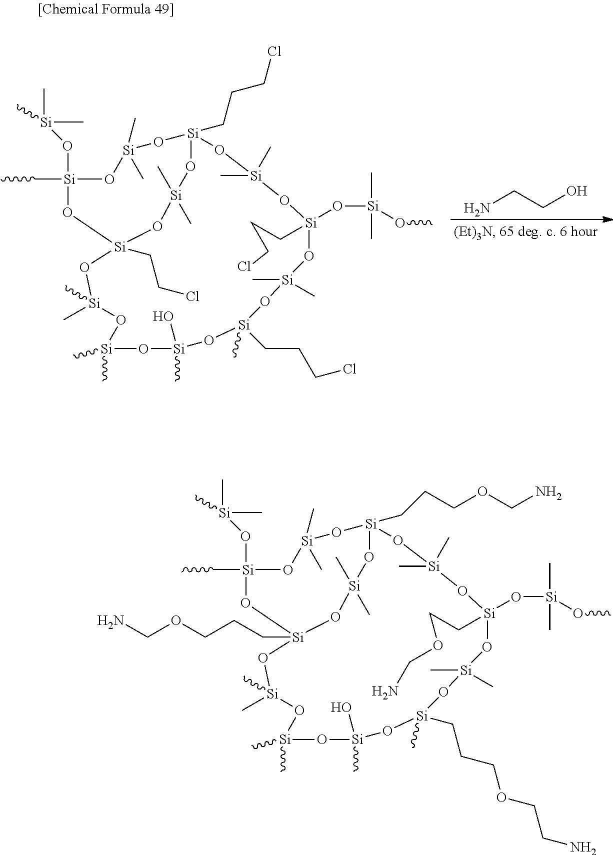

The synthesis scheme of the chelating silica xerogel from an amide silica xerogel is shown below. In the following, a wavy line represents a valence bond.

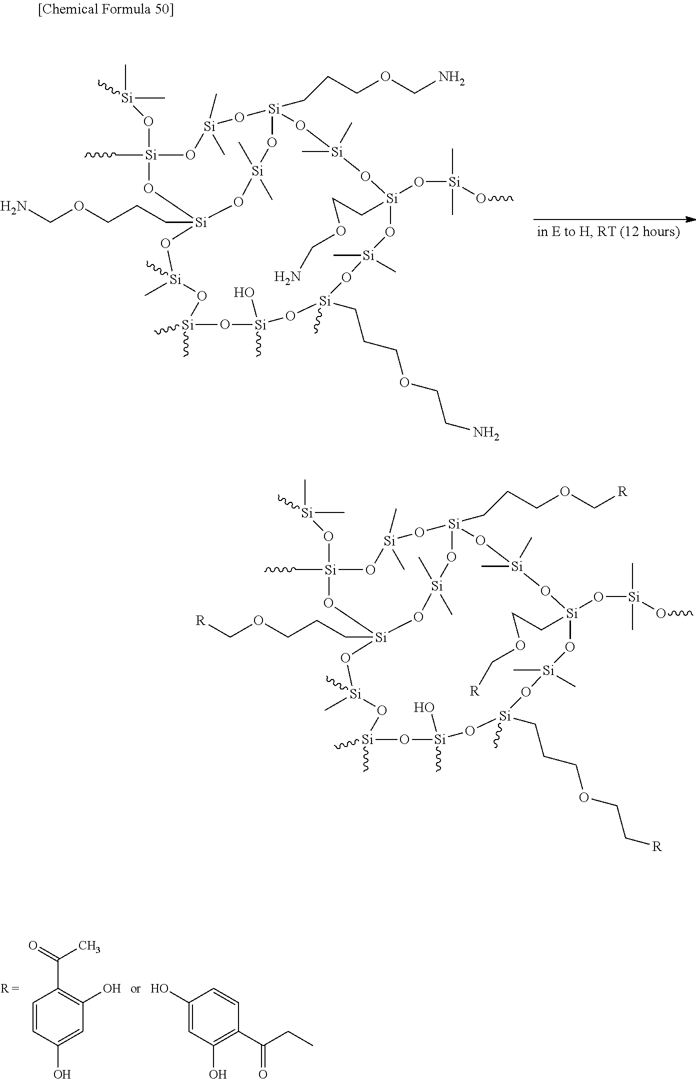

As shown in the above results, metal ions in the organic solvent were successfully removed by using the chelating silica xerogel as a filtration material. Further, it was confirmed that a novel synthetic route for chelating silica xerogels starting from a chloride silica xerogel was successfully developed.

(Synthesis of Acrylamide Crosslinked Product with Amino Group Modified with Hydrochloride)

1.2 g of N-(3-aminopropyl)methacrylamide hydrochloride, 0.5 g of a crosslinking agent (dipentaerythritol hexaacrylate) and 0.05 g of a radical initiator (V-601) were placed in a vial and dissolved in 10 mL of 2-propanol, and the resulting solution was stirred in an oil bath at 70° C. for 3 hours. After the reaction, the obtained crosslinked product was thoroughly washed with 2-propanol and then washed with diethyl ether, and vacuum dried for 1 day to obtain a white acrylamide crosslinked product with an amino group modified with hydrochloride. The chemical structure of each material used for the synthesis is described below.

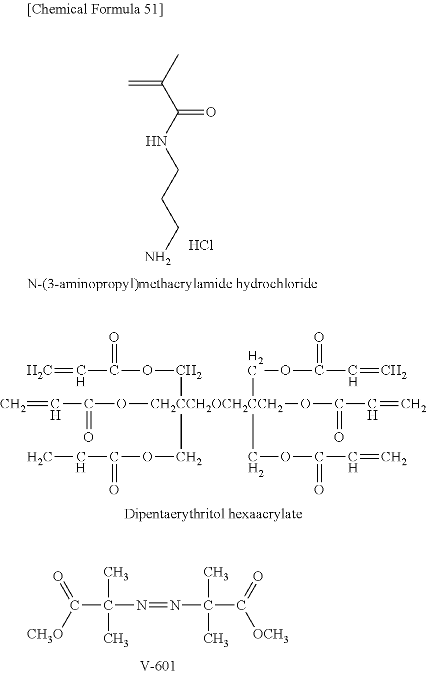

### (Synthesis of Chelate Group-Modified Acrylamide Crosslinked Product)

0.450 g of 4-hydroxybenzophenone and 3.05 g of triethylamine were dissolved in 10 mL of 2-propanol, and a reaction solution for chelate group modification was prepared in a vial. To the reaction solution, 0.5 g of the acrylamide crosslinked product with an amino group modified with hydrochloride was added, and the resulting mixture was allowed to stand in an oven at 60° C. for 24 hours. After the completion of the reaction, it was confirmed that the white powder turned yellow. The powder was washed with ethanol and then with acetone, and vacuum dried for 24 hours. The obtained powder and the acrylamide crosslinked product with an amino group modified with hydrochloride were measured by FT-IR. As a result, in the yellow powder after the reaction, a peak attributable to the OH group which was not observed in the acrylamide crosslinked product with an amino group modified with hydrochloride before the modification of the chelate group was confirmed.

Furthermore, even in the powder obtained by a chelate reaction by the same method using an acrylamide homopolymer with an amino group modified with hydrochloride, since the peak attributable to the aromatic ring was confirmed from the ¹H-NMR spectrum after the reaction, it was shown that a chelate group-modified acrylamide crosslinked product was successfully synthesized. The synthesis scheme of the chelate group-modified acrylamide crosslinked product is shown below.

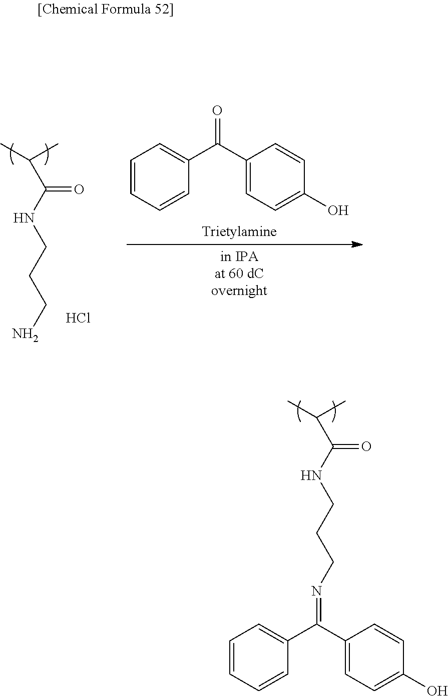

### (Evaluation of Metal Modification of Chelate Group-Modified Acrylamide Crosslinked Product)

The chelate group-modified acrylamide crosslinked product obtained above was added to a 5 μM iron chloride acetonitrile solution, the resulting mixture was left to stand after stirring, and the resulting slurry solution was filtered to remove the powder of the crosslinked product.

The obtained filtrate changed from yellow to transparent and the powder changed from yellow to orange, thereby confirming the complex formation between the chelating moiety and iron chloride. From this result, it was shown that metal ions were successfully removed from the solution using this chelate powder.

### (Preparation of Chelate Group-Modified PTFE Film)

Chelate modification was investigated on the PTFE film whose surface was modified through the crosslinking of N-(3-aminopropyl)methacrylamide hydrochloride based on the method described above. From the XPS measurement of the obtained chelate group-modified PTFE film, since disappearance of the peak of Cl2s attributable to N-(3-aminopropyl)methacrylamide hydrochloride after chelate modification was confirmed, complete chelating group modification to the film was observed. From the above result, it was shown that a chelate group-modified PTFE film was successfully prepared.

1. A filtration material comprising a silica base material having a group represented by the following general formula (a0-1): 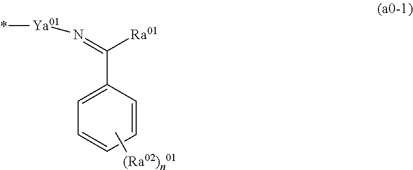
wherein Ya⁰¹ represents a divalent linking group; Ra⁰¹ represents a hydrocarbon group which may have a substituent;
Ra⁰² represents a hydroxyl group or a hydrocarbon group having 1 to 6 carbon atoms which may have a substituent; n⁰¹ represents an integer of 0 to 5; and
the symbol “*” represents a valence bond with respect to the silica base material.

2. The filtration material according to claim 1, wherein said silica base material is a porous and flexible silica fiber.

3. The filtration material according to claim 1, wherein said silica base material is a silica gel.

4. The filtration material according to claim 3, wherein said silica gel has a particle size of 2 to 50 μm.

5. The filtration material according to claim 1,
wherein said silica base material is a copolymer of an alkoxysilane having two or more functional groups, the copolymer having a partial structure represented by the following general formulas (p-1) and (p-3): 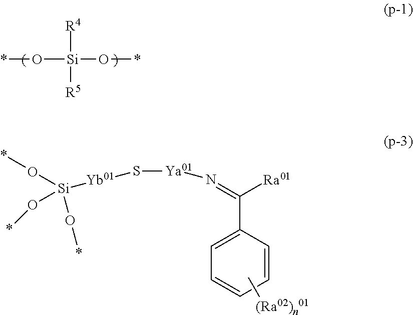
wherein R⁴ and R⁵ each independently represent a hydroxyl group or a hydrocarbon group which may have a substituent, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

6. The filtration material according to claim 1,
wherein said silica base material is a copolymer of an alkoxysilane having two or more functional groups, the copolymer having a partial structure represented by the following general formulas (p-1) and (p-5): 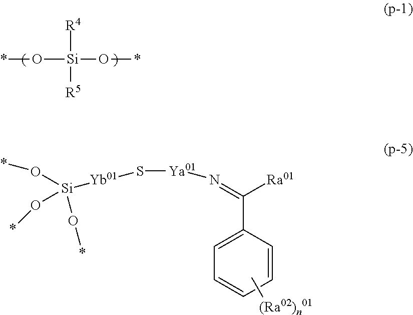
wherein R⁴ and R⁵ each independently represent a hydroxyl group or a hydrocarbon group which may have a substituent, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

7. A filtration material comprising a porous base material having a group represented by the following general formula (a0-1): 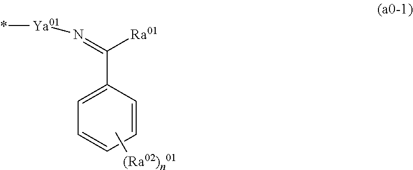
wherein Ya⁰¹ represents a divalent linking group; Ra⁰¹ represents a hydrocarbon group which may have a substituent;
Ra⁰² represents a hydroxyl group or a hydrocarbon group having 1 to 6 carbon atoms which may have a substituent; n⁰¹ represents an integer of 0 to 5; and the symbol “*” represents a valence bond with respect to the porous base material.

8. The filtration material according to claim 1, wherein said filtration material is used for filtering a resist composition or an organic solvent.

9. A filtration filter comprising the filtration material according to claim 1.

10. A filtration method comprising passing a resist composition or an organic solvent through the filtration filter according to claim 9 to remove impurities in the resist composition or the organic solvent.

11. The filtration method according to claim 10, wherein said impurities are metal components.

12. A method for producing a filtration material, comprising introducing a group represented by the following general formula (a0-1) to a porous base material having a terminal amino group: 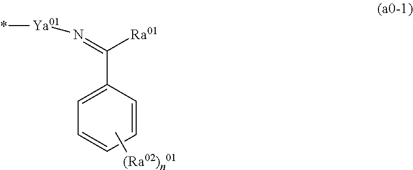
wherein Ya⁰¹ represents a divalent linking group; Ra⁰¹ represents a hydrocarbon group which may have a substituent;
Ra⁰² represents a hydroxyl group or a hydrocarbon group having 1 to 6 carbon atoms which may have a substituent; n⁰¹ represents an integer of 0 to 5; and the symbol “*” represents a valence bond with respect to the porous base material having a terminal amino group.

13. The method for producing a filtration material according to claim 12, wherein said filtration material is used for filtering a resist composition or an organic solvent.

14. The method for producing a filtration material according to claim 12, wherein said filtration material is a filtration filter.

15. A filtration method comprising passing a resist composition or an organic solvent through a filtration material obtained by the method according to claim 12 to remove impurities in the resist composition or the organic solvent.

16. The filtration method according to claim 15, wherein said impurities are metal components.

17. A copolymer of an alkoxysilane having two or more functional groups, the copolymer having a partial structure represented by the following general formulas (p-1) and (p-3): 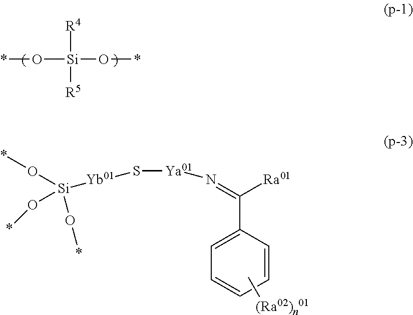
wherein R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

18. A copolymer of an alkoxysilane having two or more functional groups, the copolymer having a partial structure represented by the following general formulas (p-1) and (p-5): 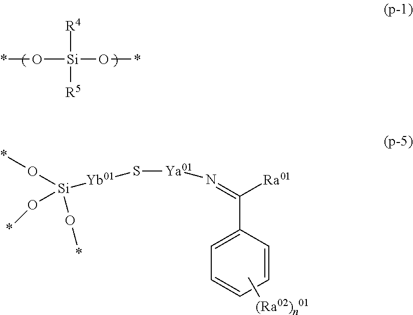
wherein R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

19. A method for producing the copolymer according to claim 17, comprising:
reacting a compound represented by the following general formula (1) with a compound represented by the following general formula (2) to obtain a copolymer (A) having a partial structure represented by the following general formulas (p-1) and (p-2);
modifying the resulting copolymer (A) to obtain a copolymer (B) having a partial structure represented by the following general formula (p-B-1); and
modifying the resulting copolymer (B) to obtain a copolymer (C) having a partial structure represented by the following general formulas (p-3) and (p-1): 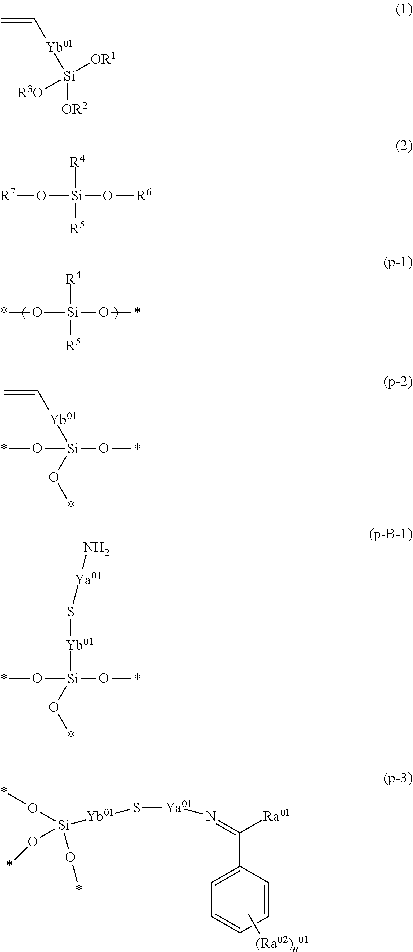
wherein R¹ to R³ and R⁶ to R⁷ each independently represent an alkyl group having 1 to 5 carbon atoms; R⁴ and R⁵ each independently represent a hydroxyl group or a hydrocarbon group which may have a substituent, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

20. A method for producing the copolymer according to claim 18, comprising:
reacting a compound represented by the following general formula (3) with a compound represented by the following general formula (2) to obtain a copolymer (X) having a partial structure represented by the following general formulas (p-1) and (p-4);
modifying the resulting copolymer (X) to obtain a copolymer (Y) having a partial structure represented by the following general formula (p-Y-1); and
modifying the resulting copolymer (Y) to obtain a copolymer (Z) having a partial structure represented by the following general formulas (p-5) and (p-1): 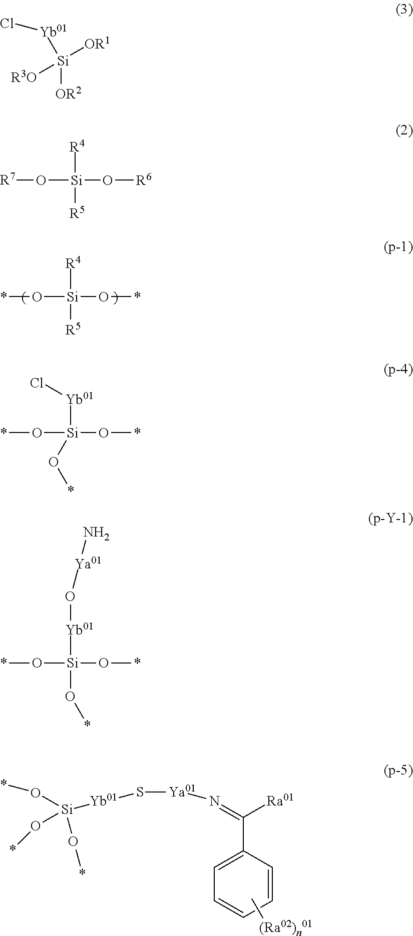
wherein R¹ to R³ and R⁶ to R⁷ each independently represent an alkyl group having 1 to 5 carbon atoms; R⁴ and R⁵ each independently represent a hydroxyl group or a hydrocarbon group which may have a substituent, and one of R⁴ and R⁵ may be bonded to another silicon atom in the alkoxysilane copolymer to form a crosslinked structure; Ya⁰¹ and Yb⁰¹ each independently represent a divalent linking group; Ra⁰¹ represents a hydrocarbon group which may have a substituent; Ra⁰² represents a hydroxyl group or a hydrocarbon group having 1 to 6 carbon atoms which may have a substituent; n⁰¹ represents an integer of 0 to 5; and the symbol “*” represents a valence bond.

21. A copolymer of an alkoxysilane having two or more functional groups, the copolymer having a partial structure represented by the following general formulas (p-1) and (p-4): 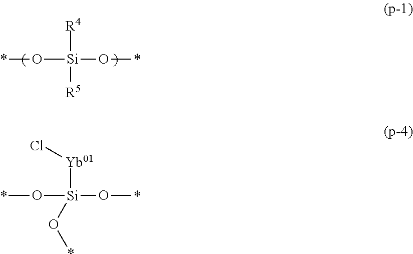
wherein R⁴ and R⁵ each independently represent a hydrocarbon group which may have a substituent or a hydroxyl group, and one of R⁴ and R⁵ may be bonded to another silicon atom in the alkoxysilane copolymer to form a crosslinked structure; Yb⁰¹ represents a divalent linking group; and the symbol “*” represents a valence bond.
